(19) United States
(12) Patent Application Publication
(10) Pub. No.: US 2025/0318442 A1
(43) Pub. Date: Oct. 9, 2025

(54) HYBRID TUNING OF SUPERCONDUCTING TUNNEL JUNCTION DEVICES

(71) Applicant: International Business Machines Corporation, Armonk, NY (US)

(72) Inventors: Martin O. Sandberg, Ossining, NY (US); Jared Barney Hertzberg, Yorktown Heights, NY (US); James Robert Rozen, Peekskill, NY (US); Eric Zhang, Sleepy Hollow, NY (US); Jason S. Orcutt, Katonah, NY (US)

(21) Appl. No.: 18/629,008

(22) Filed: Apr. 8, 2024

(51) Int. Cl. H10N 60/01; G06N 10/40; H01S 3/102

(52) U.S. Cl. CPC H10N 60/0912; H01S 3/1024; H10N 60/0884; G06N 10/40

(57) ABSTRACT

Techniques are provided for tuning junction resistances of superconducting tunnel junction devices (e.g., Josephson junctions). For example, a method comprises measuring a resistance of a superconducting tunnel junction device, determining a difference between the measured resistance of the superconducting tunnel junction device and a target resistance for the superconducting tunnel junction device, and performing a hybrid tuning process to shift a resistance of the superconducting tunnel junction device from the measured resistance to the target resistance, the hybrid tuning process comprising a laser tuning process and a controlled-current tuning process.

### BACKGROUND

This disclosure relates generally to techniques for tuning superconducting tunnel junction devices and, in particular, to techniques for tuning Josephson junctions of quantum devices such as superconducting quantum bits. A quantum computing system can be implemented using superconducting circuit quantum electrodynamics (cQED) architectures that are constructed using quantum circuit components such as, e.g., superconducting quantum bits (e.g., fixed-frequency transmon quantum bits), superconducting quantum interference devices (SQUIDs), and other types of superconducting devices which comprise Josephson junction devices. In particular, superconducting quantum bits (qubits) are electronic circuits which are implemented using components such as superconducting tunnel junction devices (e.g., Josephson junctions), inductors, and/or capacitors, etc., and which behave as quantum mechanical anharmonic (non-linear) oscillators with quantized states, when cooled to cryogenic temperatures. A fixed-frequency qubit, such as a transmon qubit, has a transition frequency (denoted f₀₁) which corresponds to an energy difference between a ground state |0 [symbol] and a first excited state |1 [symbol] of the qubit. It is known that the transition frequency f₀₁ of a qubit can be estimated from the resistance (denoted R_{J}) of the Josephson junction of the qubit.

A solid-state quantum processor can include multiple superconducting qubits that are arranged in a given lattice structure (e.g., square lattice, heavy hexagonal lattice) to enable quantum information processing through quantum gate operations (e.g., single-qubit gate operations and multi-qubit gate operations) in which quantum information is generated and encoded in computational basis states (e.g., |0 [symbol] and |1 [symbol] ) of single qubits, superpositions of the computational basis states of single qubits, and/or entangled states of multiple qubits. Continuing technological advances in quantum processor design are enabling the rapid scaling of both the physical number of superconducting qubits and the computational capabilities of quantum processors. Indeed, while current state-of-the art quantum processors have greater than 50 qubits, it is anticipated that future quantum processors will have a much larger number of qubits, e.g., on the order of hundreds or thousands of qubits, or more.

Scaling the number of qubits (e.g., fixed frequency transmon qubits) in a qubit lattice, while maintaining high-fidelity quantum gate operations, remains a key challenge for quantum computing. For example, as superconducting quantum processors scale to larger numbers of qubits, frequency crowding within a qubit lattice becomes increasingly problematic since the transition frequencies of the qubits need to be precisely controlled to minimize gate errors that can arise from lattice frequency collisions (e.g., improper detuning between superconducting qubits can reduce the fidelity of multi-qubit gate entanglement operations). Due to semiconductor processing variabilities, however, the transition frequencies of superconducting qubits as fabricated can deviate from design targets. In this regard, it is desirable to utilize techniques for tuning qubit frequencies post-fabrication, e.g., selectively tune fixed-frequency qubits of a given qubit lattice into desired frequency patterns, to increase collision-free yield of fixed-frequency qubit lattices.

### SUMMARY

Exemplary embodiments of the disclosure include techniques for tuning junction resistances of superconducting tunnel junction devices (e.g., Josephson junctions).

For example, an exemplary embodiment includes a method which comprises: measuring a resistance of a superconducting tunnel junction device; determining a difference between the measured resistance of the superconducting tunnel junction device and a target resistance for the superconducting tunnel junction device; and performing a hybrid tuning process to shift a resistance of the superconducting tunnel junction device from the measured resistance to the target resistance, the hybrid tuning process comprising a laser tuning process and a controlled-current tuning process.

Advantageously, an exemplary hybrid tuning process using a combination of laser tuning and controlled-current tuning of superconducting tunnel junction devices, such as Josephson junctions, provides improved precision and wider tuning range for tuning junction resistances of the superconducting tunnel junction devices.

In another exemplary embodiment, as may be combined with the preceding paragraphs, the hybrid tuning process comprises: performing the laser tuning process to shift the resistance of the superconducting tunnel junction device towards the target resistance; and in response to determining that the target resistance cannot be reached using the laser tuning process, performing the controlled-current tuning process by applying a controlled tuning current to the superconducting tunnel junction device to shift the resistance of the superconducting tunnel junction device to the target resistance.

In another exemplary embodiment, as may be combined with the preceding paragraphs, performing the laser tuning process comprises: utilizing tuning calibration data to determine a set of laser annealing parameters, based at least on the determined difference between the measured resistance of the superconducting tunnel junction device and the target resistance; and utilizing the determined set of laser annealing parameters to configure the laser tuning process to laser anneal the superconducting tunnel junction device.

In another exemplary embodiment, as may be combined with the preceding paragraphs, the set of laser annealing parameters comprises at least a laser power setting and an anneal time, for a given laser beam illumination pattern.

In another exemplary embodiment, as may be combined with the preceding paragraphs, performing the controlled-current tuning process comprises: utilizing tuning calibration data to determine a set of tuning current parameters, based at least on a remaining amount of resistance shift which is needed following the laser tuning process to reach the target resistance of the superconducting tunnel junction device; and utilizing the determined set of tuning current parameters to configure the controlled-current tuning process to apply a controlled tuning current to the superconducting tunnel junction device.

In another exemplary embodiment, as may be combined with the preceding paragraphs, the controlled tuning current comprises a direct current (DC) current pulse, and the set of tuning current parameters for the DC current pulse comprises at least one of pulse amplitude and pulse duration.

In another exemplary embodiment, as may be combined with the preceding paragraphs, the controlled tuning current comprises an alternating current (AC) current pulse, and the set of tuning current parameters for the AC current pulse comprises at least one of peak amplitude, peak-to-peak amplitude, duration, frequency, pulse envelope shape, and DC offset.

Another exemplary embodiment includes a method which comprises performing a tuning process to tune a transition frequency of at least one superconducting quantum bit of a quantum bit array on a quantum chip, wherein performing the tuning process comprises: measuring a resistance of a Josephson junction of the at least one superconducting quantum bit; determining a difference between the measured resistance of the Josephson junction and a target resistance for the Josephson junction which corresponds to a target transition frequency of the at least one superconducting quantum bit as specified in a frequency tuning plan for the quantum bit array; and performing a hybrid tuning process to shift a resistance of the Josephson junction of the at least one superconducting quantum bit from the measured resistance to the target resistance, the hybrid tuning process comprising a laser tuning process and a controlled-current tuning process.

Another exemplary embodiment includes a method which comprises: measuring a resistance of a superconducting tunnel junction device; utilizing tuning calibration data to determine a controlled tuning current to apply to the superconducting tunnel junction device to shift a resistance of the superconducting tunnel junction device from the measured resistance to a target resistance; and applying the controlled tuning current to the superconducting tunnel junction device to shift the resistance of the superconducting tunnel junction device to the target resistance.

Another exemplary embodiment includes a method which comprises: performing hybrid tuning calibration operations on first Josephson junctions by (i) performing laser annealing operations to laser anneal the first Josephson junctions using different combinations of laser annealing parameters and (ii) applying controlled tuning currents with different combinations of tuning current parameters, to the first Josephson junctions; determining junction resistance shifts of the first Josephson junctions as a result of the laser annealing calibration operations and applying the controlled tuning currents to the first Josephson junctions; and utilizing the determined junction resistance shifts of the first Josephson junctions to determine calibration data for configuring a hybrid tuning process, which comprises a laser tuning process and a controlled-current tuning process, for tuning second Josephson junctions that correspond to the first Josephson junctions.

Another exemplary embodiment includes a system which comprises a laser annealing apparatus, a prober apparatus, and a control system operatively coupled to the laser annealing apparatus and the prober apparatus. The control system is configured to control the laser annealing apparatus and the prober apparatus to perform a tuning process for tuning a transition frequency of at least one superconducting quantum bit of a quantum bit array on a quantum chip. In performing the tuning process, the control system is configured to: utilize the prober apparatus to measure a resistance of a Josephson junction of the at least one superconducting quantum bit; determine a difference between the measured resistance of the Josephson junction and a target resistance for the Josephson junction which corresponds to a target transition frequency of the at least one superconducting quantum bit as specified in a frequency tuning plan for the quantum bit array; and utilize the laser annealing apparatus and the prober apparatus to perform a hybrid tuning process to shift a resistance of the Josephson junction of the at least one superconducting quantum bit from the measured resistance to the target resistance, the hybrid tuning process comprising a laser tuning process and a controlled-current tuning process.

Other embodiments will be described in the following detailed description of exemplary embodiments, which is to be read in conjunction with the accompanying figures.

### BRIEF DESCRIPTION OF THE DRAWINGS

FIG. 1 schematically illustrates a system for tuning superconducting quantum devices, according to an exemplary embodiment of the disclosure.

FIG. 2A schematically illustrates a method for measuring and tuning a junction resistance of a Josephson junction, according to an exemplary embodiment of the disclosure.

FIGS. 2B, 2C, 2D, 2E, and 2F illustrate various profiles of tuning currents that can be utilized for tuning a junction resistance of a Josephson junction, according to exemplary embodiments of the disclosure.

FIGS. 3A, 3B, 3C, 3D, and 3E depict graphs of tuning curves for tuning junction resistances of Josephson junctions, according to exemplary embodiments of the disclosure.

FIG. 4 illustrates a flow diagram of a method for tuning junction resistances of Josephson junctions using a controlled-current tuning process, according to an exemplary embodiment of the disclosure.

FIG. 5 illustrates a flow diagram of a calibration process for obtaining tuning calibration data for use in tuning junction resistances of Josephson junctions using a controlled-current tuning process, according to an exemplary embodiment of the disclosure.

FIG. 6 illustrates a flow diagram of a process for performing calibration tests on Josephson junctions to obtain tuning calibration data, according to an exemplary embodiment of the disclosure.

FIG. 7 illustrates a flow diagram of a process for analyzing tuning calibration data to determine tuning curves and associated calibration parameters for tuning junction resistances of Josephson junctions using a controlled-current tuning process, according to an exemplary embodiment of the disclosure.

FIG. 8 illustrates a flow diagram of a method for tuning junction resistances of Josephson junctions using a controlled-current tuning process, according to another exemplary embodiment of the disclosure.

FIG. 9 illustrates a flow diagram of a method for generating and updating a frequency tuning plan of a quantum bit array, according to an exemplary embodiment of the disclosure.

FIGS. 10A and 10B are flow diagrams which illustrate a hybrid calibration process to obtain tuning calibration data for using in configuring a hybrid tuning process for laser tuning and controlled-current tuning of Josephson junctions, according to an exemplary embodiment of the disclosure.

FIG. 11 illustrates a flow diagram of a method for performing a hybrid tuning process to tune junction resistances of Josephson junctions using combination of laser tuning and controlled-current tuning, according to an exemplary embodiment of the disclosure.

FIG. 12 illustrates a flow diagram of a method of a laser tuning process which can be implemented in the hybrid tuning process of FIG. 11, according to according to an exemplary embodiment of the disclosure.

FIGS. 13A and 13B schematically illustrate methods for laser annealing a quantum device using different laser beam illumination patterns, according to an exemplary embodiment of the disclosure.

FIG. 14 schematically illustrates an exemplary architecture of a computing environment for implementing a control system that is configured to control a system for tuning superconducting quantum devices, according to an exemplary embodiment of the disclosure.

### DETAILED DESCRIPTION

Exemplary embodiments of the disclosure will now be described in further detail with regard to techniques for tuning junction resistances of superconducting tunnel junction devices (e.g., Josephson junctions). In some embodiments, the junction resistances of superconducting tunnel junction devices are tuned by applying controlled tuning currents (e.g., current pulses) to shift the junction resistances of the superconducting tunnel junction devices toward target resistances. A controlled tuning current can be a DC current pulse with a given set of DC tuning current parameters (e.g., pulse amplitude, pulse duration, etc.) or an AC current pulse with a given set of AC tuning current parameters (e.g., one or more frequencies, a peak-to-peak amplitude, a peak amplitude, duration, a pulse envelope shape, etc.), which are applied to a superconducting tunnel junction device to shift the respective junction resistance to target resistances. In other embodiments, the junction resistances of superconducting tunnel junction devices are tuned using a hybrid tuning process which performs laser tuning and controlled-current tuning. The exemplary tuning techniques as disclosed herein can be implemented to tune the junction resistances of Josephson junctions of superconducting qubits, post fabrication, to tune the transition frequencies of the superconducting qubits to target transition frequencies based on, e.g., a frequency tuning plan for superconducting qubits of a given qubit lattice and, thereby, enable frequency collision avoidance in multi-qubit lattices of a given topology (e.g., a heavy-hexagonal lattice, a square lattice, and the like). Advantageously, as explained in further detail below, an exemplary hybrid tuning process using a combination of laser tuning and controlled-current tuning of superconducting tunnel junction devices, such as Josephson junctions, provides improved precision and wider tuning range for tuning junction resistances of the superconducting tunnel junction devices.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means serving as an example, instance, or illustration. Any embodiment or design described herein as “exemplary” is not to be construed as preferred or advantageous over other embodiments or designs. In addition, the terms “about” or “substantially” as used herein with regard to, e.g., percentages, ranges, etc., are meant to denote being close or approximate to, but not exactly. For example, the term “about” or “substantially” as used herein implies that a small margin of error may be present, such as 1% or less than the stated amount.

It is to be further understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

Further, the term “quantum chip” as used herein is meant to broadly refer to any device which comprises superconducting quantum devices including, e.g., superconducting qubits and other types of quantum devices which implement superconducting tunnel junction devices (e.g., Josephson junctions). For example, a quantum chip can comprise a semiconductor die onto which is formed an array (lattice) of qubits, which is fabricated on a wafer comprising multiple dies, and which can be diced (cut) from the wafer using a die singulation process to provide a singulated die. In some instances, a quantum chip can be a wafer with multiple dies. In the context of quantum computing, a quantum chip may comprise one or more processors for a quantum computer.

As is known in the art, a Josephson junction is a nonlinear element which is based on a dissipation-less tunneling of Cooper pairs between two superconducting elements that are coupled by a weak link (e.g., a thin insulating barrier). The Josephson effect produces a current (referred to as a supercurrent), that flows continuously without dissipation through the Josephson junction, and without a voltage applied across the Josephson junction. In particular, a Josephson junction is a nonlinear device which has a nonlinear Josephson inductance L_{J} that is determined as:

$${L}_{J} = \frac{{Φ}_{0}}{2 π {I}_{c} cos φ} ,$$

I_{c} denotes a critical current of the Josephson junction, where Φ₀ denotes the magnetic flux quantum,

$${Φ}_{0} = \frac{h}{2 e} ,$$

and where φ denotes a superconducting phase difference across the Josephson junction, i.e., φ=φ₁−φ₂. The Josephson inductance L_{J} is non-linear with respect to φ. As is known in the art, the magnetic flux quantum Φ₀ is a fundamental unit of superconducting magnetic flux which represents a quantization of magnetic flux threading a superconducting loop, wherein Φ₀=h/(2e)≈2.07×10⁻¹⁵ Weber (volt-seconds), where h is the Planck constant, and where e denotes a magnitude of electron charge.

Further, the junction critical current I_{c} denotes a maximum amount of current that can coherently tunnel through the junction while exhibiting no dissipation, where the junction critical current is determined by

$${I}_{c} = \frac{2 {eE}_{J}}{h} .$$

The junction critical current I_{c} is a function of a Josephson energy E_{J} of the Josephson junction, wherein

$${E}_{J} = {L}_{J 0} {I}_{C}^{2} ,$$

wherein L_{J0} denotes the maximum Josephson inductance of the Josephson junction. For currents smaller than the critical current I_{c}, the Josephson junction behaves as a nonlinear inductor. Furthermore, with a Josephson junction, a resulting superconducting current I which flows through the tunnel junction, and junction voltage V across the tunnel junction, are related to the superconducting phase difference φ=φ₁−φ₂ as follows: I=I_{c} sin φ, and

$$V = \frac{{Φ}_{0} d φ}{2 π dt} .$$

Typically, superconducting qubits are implemented using at least one Josephson junction that is shunted by a superconducting capacitor. The Josephson junction functions as a nonlinear inductor which, when shunted with a capacitor, forms an anharmonic LC oscillator with individually addressable energy levels. For example, a transmon qubit is a type of superconducting qubit which comprises a Josephson junction that is shunted by a capacitor to form an anharmonic LC oscillator in which the two lowest energy level corresponding to the ground state |0 [symbol] and the first excited state |1 [symbol] are utilized as the computational basis for encoding quantum data. A superconducting transmon qubit has a transition frequency f₀₁ (or eigen frequency) which is determined based on the Josephson energy E_{J} and a charging energy E_{C} of the transmon qubit.

In particular, the transition frequency f₀₁ of a superconducting transmon qubit is determined as ωh=\sqrt{8E_{J}E_{C}}−E_{C}, where ω=2πf₀₁, and where

$$ℏ = \frac{h}{2 π} .$$

The charging energy E_{C} is inversely proportional to a total capacitance C of the superconducting transmon qubit, wherein the charging energy is determined as

$${E}_{C} = \frac{{e}^{2}}{2 C} .$$

The Josephson energy E_{J} is proportional to the critical current, and is determined as

$${E}_{J} = {I}_{c} \frac{ℏ}{2 e} = \frac{π Δ}{2 e {R}_{n}} \cdot \frac{ℏ}{2 e} ,$$

where Δ denotes a superconducting gap, and where Rₙ denotes a “normal state” junction resistance of the Josephson junction of the transmon qubit (e.g., at or near room temperature) when the metal of the qubit is not superconducting. For instance, when measured at room temperature, the junction exhibits a “normal state” resistance. These equations illustrate that the transition frequency of a transmon qubit can be varied by varying the total capacitance C of the transmon qubit and/or the normal state junction resistance Rₙ of the Josephson junction of the transmon qubit.

A standard process for fabricating superconducting tunnel junction devices, such as Josephson junctions for superconducting qubits, is based on scanning electron-beam lithography and double-angle shadow evaporation techniques which utilize shadow evaporation masks to fabricate overlapping electrodes of a superconducting tunnel junction device, with an intermediate in-situ oxidation to form a junction barrier between the overlapping electrodes. Such techniques can be used to fabricate Josephson junctions having either Dolan or Manhattan patterns, as is known in the art. In some embodiments, the overlapping electrodes of the Josephson junctions are fabricated using evaporated aluminum (Al), where an in-situ oxidation is performed after a first angle evaporation process to form an aluminum oxide (AlOx) layer on surfaces of the aluminum electrodes that are formed as a result of the first angle evaporation process. The double-angle shadow aluminum evaporation process results in the formation of Josephson junctions each comprising a three-layer stack of Al/AlOx/Al where the tunneling occurs across the aluminum oxide tunnel barrier layer.

The primary variables that affect the “normal state” junction resistance, and therefore the Josephson energy of Josephson junctions, are the overlap area between the two junction electrodes and the thickness of the tunnel barrier layer therebetween. For example, the critical current of a Josephson junction will be determined by the overlap area of the first and second electrodes (e.g., Al electrodes) of the Josephson junction and the thickness of the tunnel barrier layer (e.g., AlOx) between the first and second electrodes. Even when prepared using high-resolution e-beam lithography, the spread in resistance among junctions on a given chip is at best on the order 2%. Some of this resistance spread could be result of the microscopic structure of the barrier where tunneling depends exponentially on the thickness of the tunnel barrier layer. It has been suggested that as little as 10% of the area of the Josephson junction may contribute to the tunneling current due to the nonuniform thickness of the tunnel barrier layer. Therefore, it is highly desirable to implement techniques for tuning the junction resistance of the Josephson junctions, post fabrication, to thereby reduce the resistance spread, and hence also reduce the frequency spread of qubits.

Indeed, the ability to tune the frequency of superconducting qubits (e.g., transmon qubits) to a high degree of accuracy, post fabrication, is important for scaling the number of qubits for quantum processing. For example, in a relatively large qubit lattice, if the transition frequencies of the qubits are not well-controlled, frequency collisions in the qubit lattice can easily arise. Frequency collisions are conditions where the alignment of qubit frequencies causes unwanted interaction and gate degradation. For a typical quantum device that implements cross resonance (CR) gates, there are at least 7 types of frequency collisions that may arise between pairs of qubits lying at nearest neighbor or next-nearest-neighbor sites in the lattice.

As noted above, exemplary embodiments of the disclosure provide systems and methods for tuning junction resistances of superconducting tunnel junction devices (e.g., Josephson junctions) using controlled-current tuning and/or laser tuning techniques to change the “normal state” junction resistance Rₙ of superconducting tunnel junction devices (e.g., Josephson junctions), post fabrication. In some embodiments, a controlled-current tuning process is performed by applying controlled tuning currents (e.g., current pulses) to shift the junction resistances of superconducting tunnel junction devices towards their respective target junction resistances. The controlled tuning currents are applied to the superconducting tunnel junction devices in their normal state (e.g., at or near room temperature) to shift the junction resistance of the superconducting tunnel junction devices. As explained in further detail below, the controlled-current tuning techniques can be performed using a same prober system for measuring the junction resistances of the Josephson junctions as well as applying the controlled tuning currents to the Josephson junctions.

Moreover, in some embodiments, a laser tuning process, e.g., Laser Annealing of Stochastically Impaired Qubits (LASIQ), is performed to tune the transition frequencies of superconducting qubits, post fabrication, by laser tuning junction resistances of the qubit Josephson junctions, and thereby selectively tune fixed-frequency qubits of a given qubit lattice into desired frequency pattern to increase collision-free yield of fixed-frequency qubit lattices. The exemplary laser tuning methods utilize laser energy to cause localized thermal annealing of the Josephson junctions of qubits to adjust and stabilize the junction resistance Rₙ of the Josephson junctions and, thereby, tune the respective qubit transition frequencies (f₀₁) with high precision. A LASIQ process is utilized to tune the transition frequencies of superconducting qubits, post fabrication, to selectively tune fixed-frequency qubits of a given qubit lattice into desired frequency pattern to increase collision-free yield of fixed-frequency qubit lattices.

In other embodiments, a hybrid tuning process is implemented to tune the junction resistances of superconducting tunnel junction devices (e.g., Josephson junctions) using a combination of laser tuning and controlled-current tuning to tune the junction resistances of, e.g., Josephson junctions of qubits. For example, in some embodiments, laser tuning process is initially performed to tune the junction resistances of Josephson junctions of qubits to respective target junction resistances, as specified by a frequency tuning plan. In instances, where the target junction resistances of one or more of the Josephson junctions cannot be reached using laser tuning, the tuning proceeds using a controlled-current tuning process to further shift the junction resistances of such Josephson junctions towards their respective target junction resistances.

For illustrative purposes, the exemplary embodiments will be described in the context of tuning junction resistances of Josephson junctions and, in particular, tuning junction resistances of Josephson junctions of superconducting qubits (e.g., transmon qubits) to tune the transition frequencies of the superconducting qubits. It is to be understood, however, that the exemplary current tuning techniques can be implemented to tune the junction resistances of superconducting tunnel junction devices (e.g., Josephson junctions) that are implemented in other types of quantum devices including, but not limited to, superconducting quantum interference devices (SQUIDs), flux-tunable qubit couplers, parametric modulator circuits, parametric amplifier circuits, Josephson junction ring modulators, and other types of superconducting devices which comprise Josephson junction devices

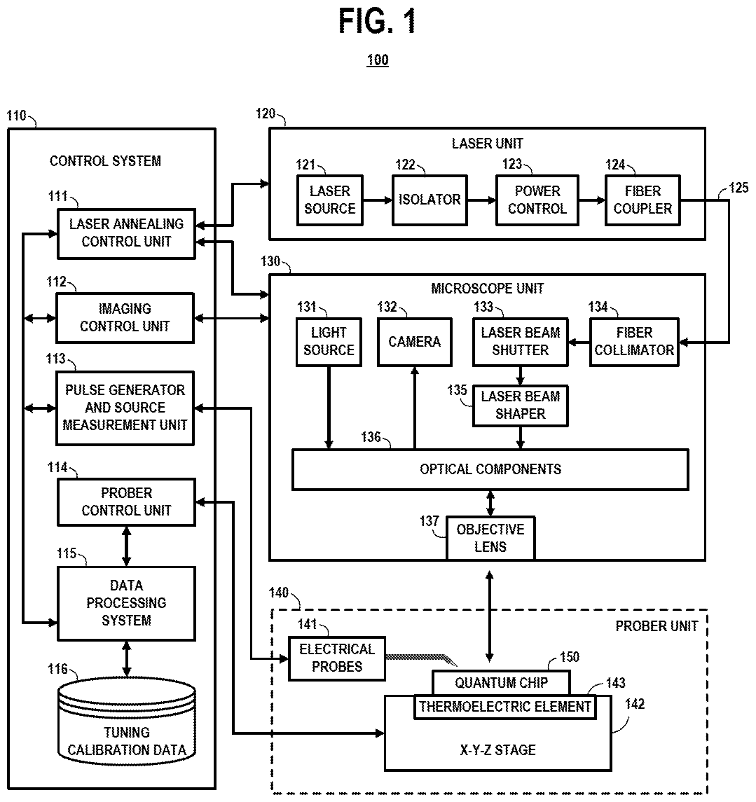

FIG. 1 schematically illustrates a system for tuning superconducting quantum devices, according to an exemplary embodiment of the disclosure. In particular, FIG. 1 schematically illustrates a system 100 that is configured to perform laser tuning and controlled-current tuning methods for tuning junction resistances of superconducting tunnel junction devices (e.g., Josephson junctions), post fabrication. The system 100 comprises a control system 110, a laser unit 120, an optical fiber 125, a microscope unit 130, and a prober unit 140. The control system 110 comprises a laser annealing control unit 111, an imaging control unit 112, a pulse generator and source measurement unit (SMU) 113, a prober control unit 114, a data processing system 115, and a database of tuning calibration data 116. The laser unit 120 comprises a laser source 121, an isolator 122, a laser power control block 123, and a fiber coupler 124. The microscope unit 130 comprises a light source 131, a camera 132, a laser beam shutter 133, a fiber collimator 134, a laser beam shaper 135, a plurality of optical components 136, and an objective lens 137.

The prober unit 140 comprises electrical probes 141 (e.g., probe card), and an X-Y-Z stage 142 which comprises a wafer chuck with a thermoelectric element 143. A quantum chip 150 (or any other similar device under test) can be mounted to the X-Y-Z stage 142. In some embodiments, the quantum chip 150 comprises a lattice of superconducting qubits, where each superconducting qubit comprises at least one respective Josephson junction which can be tuned (via laser tuning and/or controlled-current tuning) using the system 100 to tune the junction resistance and, thus, tune the transition frequency of the superconducting qubit, post-fabrication.

In some embodiments, the laser unit 120 and the microscope unit 130 comprise modular units which collectively comprise a laser annealing apparatus, and which are coupled together via the optical fiber 125. In some embodiments, the optical fiber 125 comprises a single-mode (SM) polarization-maintaining (PM) optical fiber, which is configured to preserve a linear polarization of linearly polarized light that is injected into the optical fiber 125 by the laser unit 120 and propagated to the microscope unit 130. The microscope unit 130 comprises a modular optical unit which comprises visible light and laser optical components. The microscope unit 130 can be integrated onto the prober unit 140 (e.g., a wafer-scale prober). In this regard, in some embodiments, the laser unit 120, the microscope unit 130, and the prober unit 140 can be physically coupled/attached to each other to form an integrated laser annealing apparatus which is configured to perform laser anneal operations for tuning junction resistances of Josephson junctions, as well as performing in-situ junction resistance measurements and controlled-current tuning operations, under the control of the control system 110. In some embodiments, the control system 110 is operatively/communicatively coupled to the laser unit 120, the microscope unit 130, and the prober unit 140 via wires and/or wirelessly. The control system 110 comprises hardware and/or software for automated control of various operations of the laser unit 120, the microscope unit 130, and the prober unit 140 of the system 100.

The laser unit 120 is configured to generate a laser beam that is used by the microscope unit 130 to generate a laser beam illumination pattern which comprises a single-spot or multi-spot beam pattern for laser annealing a given Josephson junction. In some embodiments, the laser source 121 comprises a solid-state diode pump to generate laser energy, and a laser head to generate a focused laser beam from the laser energy emitted from the solid-state diode pump. In some embodiments, the diode pump comprises a 532 nanometer (nm) (frequency doubled) diode-pumped solid-state laser (e.g., a second harmonic generation (SHG) laser). In some embodiments, the power level of the laser source 121 (e.g., solid-state diode pump) can be adjusted by the control system 110. For example, the power level of the laser source 121 can be set to one of a plurality of different power level settings (e.g., lower power, medium power, high power settings). The isolator 122 is configured to provide polarization cleanup and optical isolation to mitigate unwanted feedback to the laser head of the laser source 121.

The laser power control block 123 is configured to actively control and calibrate the power of the focused laser beam. For example, in some embodiments, the laser power control block 123 comprises a half-wave plate, and a polarizing beam-splitter (PBS) coupled to a dump. The half-wave plate is configured to shift the polarization direction of the laser beam output from the isolator 122. The laser power control block 123 further comprises a power monitor which comprises, e.g., an optical wedge that is configured to divert some laser beam power to a silicon photodiode. The silicon photodiode generates an electrical signal that is indicative of the laser power level, and the electrical signal is feedback to the control system 110 (e.g., the laser annealing control unit 111), the control system 110 generates control signals that are applied to the laser power control block 123 to adjustably control the laser power, as directed, for laser tuning of Josephson junctions. More specifically, in some embodiments, the power level of the laser beam can be coarsely adjusted by controlling the power output of the laser source 121, while the power level of the laser beam can be finely adjusted by operation of the laser power control block 123.

For example, in some embodiments, the half-wave plate of the laser power control block 123 is configured to shift the polarization direction of the laser beam output from the isolator 122, and the half-wave plate comprises an adjustable rotation, which can be electronically-controlled via the laser annealing control unit 111 to adjust a total attenuation by rotating the polarization incident on the polarizing beam splitter to the desired power level. In some embodiments, the polarizing beam splitter of the laser power control block 123 comprises an optical filter that allows a specific polarization of light waves associated with the laser beam to pass through the optical filter and blocks light waves of other polarizations, to thereby generate a laser beam with well-defined polarized light.

The polarized laser light generated by the laser unit 120 is coupled into the optical fiber 125 via the 1 fiber coupler 124, and propagates to the microscope unit 130. In the microscope unit 130, the fiber collimator 134 (e.g., collimating lens) is configured to transform the laser light which is output from the optical fiber 125 into a free-space collimated beam. In some embodiments, the microscope unit 130 comprises a power monitor which comprises, e.g., a beam sampler (e.g., beam splitter) and photodiode, to monitor the power of the collimated laser beam to enable precise exposure control downstream from the power control/adjustment mechanisms provided by the laser unit 120.

Furthermore, in the microscope unit 130, the laser beam shutter 133 comprises an electronic shutter that is operated under control of, e.g., the laser annealing control unit 111 of the control system 110, to control the time duration of laser exposure when annealing a given Josephson junction. For example, the laser beam shutter 133 can be opened for a given duration of time when annealing a target Josephson junction to allow annealing laser beams to be projected onto the quantum chip 150 in proximity to the target Josephson junction, and then automatically closed after the given duration of time. In this regard, the laser power level and the pulse duration (laser exposure) can be controlled to achieve a desired resistance shift of the annealed Josephson junction.

The laser beam shaper 135 is configured to split the collimated laser beam (which passes through the laser beam shutter 133) into two or more laser beams with slightly different angles relative to one another. In some embodiments, the laser beam shaper 135 comprises a diffractive optical element (DOE), such as a diffractive beam splitter which splits a single laser beam into several beams (diffraction orders) in a predefined configuration. For example, in some embodiments, the diffractive beam splitter comprises a holographic optical element that imparts a precise angle (e.g., a 0.5 degree shift) to the incoming laser beam in plus and minus angular directions relative to a reference plane, to thereby generate a plurality of outgoing laser beams (e.g., 2 laser beam spot pattern, 4 laser beam spot pattern, etc.).

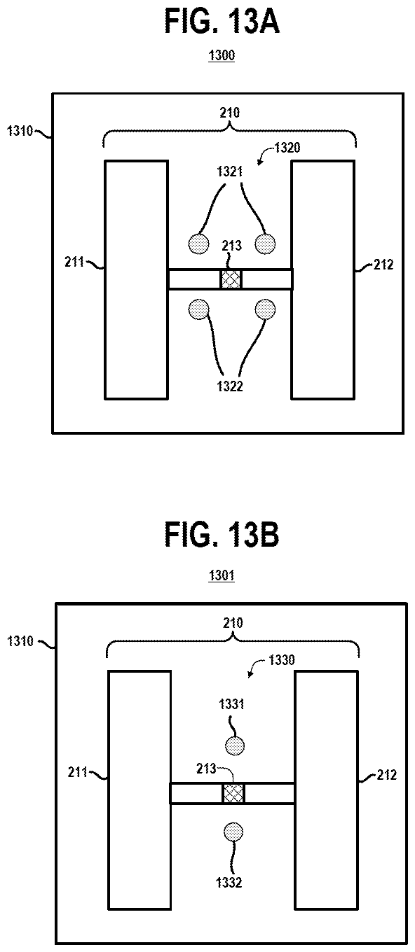

The number of laser beams generated by the laser beam shaper 135 can vary depending on the given application. For example, in some embodiments, laser beam shaper 135 comprises a 2-by-2 diffractive beam splitter, which splits the single collimated laser beam into four separate laser beams, which results in a final quad-spot illumination pattern that is projected onto the surface of the quantum chip 150 at a target location, an exemplary embodiment of which will be discussed below in conjunction with FIG. 13A. In some embodiments, the laser beam shaper 135 can be switched either manually or automatically with a different diffractive beam splitter (e.g., a plurality of DOEs on a rotary stage) to obtain a different laser spot pattern, as desired. In this regard, different diffractive beam splitters can be selected for use to generate any desired number (e.g., 2, 3, 5, 6, etc.) of laser beams with defined illumination patterns tailored to different applications.

The microscope unit 130 implements the light source 131 and the camera 132 for illuminating and viewing target features (e.g., qubits and corresponding Josephson junctions) on the surface of the quantum chip 150 within a given field of view (FOV) of the microscope unit 130. In some embodiments, the light source 131 comprises any suitable light generating device including one or more light emitting diodes (LEDs) with desired photonic wavelengths, a monochromatic light source, etc. The light source 131 together with some of the optical components 136 in the optical viewing path implement Kohler illumination to create uniform illumination of the target features in the FOV of the microscope unit 130 and to ensure that an image of the light source 131 is not visible in the images captured by the camera 132.

In some embodiments, the camera 132 comprises a charge-coupled device (CCD) image sensor, or an infrared (IR) complementary metal oxide semiconductor (CMOS) image sensor. The camera 132 is utilized to capture images of a target region on the surface of the quantum chip 150 to facilitate, e.g., aligning the electrical probes 141 to contact electrodes when performing in-situ Josephson junction resistance measurements and controlled-current tuning operations, and aligning a laser beam pattern onto the target region when performing laser annealing operations of a laser tuning process, etc. For example, in some embodiments, the Josephson junction of a given qubit is aligned to the center of the FOV of the microscope unit 130 using pattern recognition to, e.g., a Josephson junction template image. Also, in some embodiments, more than one camera may be used in parallel, by splitting the image path using a beam splitter and using, for example, an IR CMOS camera in addition to a visible wavelength camera, which may be used for process monitoring (e.g., a wide FOV for inspection, process tracking, or the like).

The optical components 136 include various types of optical components for directing, reflecting, focusing, modifying, and shaping, etc., the optical signals (e.g., laser beams for annealing, and visible light/IR light for viewing) as needed for the given application. For example, the optical components 136 include components such as a mirror, beam splitters, filters, polarizers, and various lenses such as a tube lens, an objective lens, relay lenses, etc.). The objective lens 137 is the lens that is located closest to the device under test (quantum chip 150) and serves to provide the base magnification for generating a magnified image that is viewed by the camera 132, and to project the annealing laser beam pattern (e.g., quad-spot pattern) onto the surface of the quantum chip 150. In some embodiments, the objective lens 137 comprises a long working distance (WD) objective lens. In an exemplary non-limiting embodiment, the objective lens 137 (together with an optional second objective lens) is configured to condense the laser beams and multi-spot pattern by 4×, while providing 20× image magnification.

The prober unit 140 is configured to automatically move the position of the quantum chip 150 during a tuning process (e.g., laser tuning process or controlled-current tuning process) to align a target Josephson junction of a given qubit within the FOV of the microscope unit 130 to perform a given operation, e.g., in-situ Josephson junction resistance measurement, applying a controlled tuning current to a target Josephson junction, or laser annealing a target Josephson junction, etc. In particular, the quantum chip 150 is mounted to the automated X-Y-Z stage 142 which is controllably moved in three dimensions to align features of the quantum chip 150 within the FOV of the microscope unit 130 and enable contact between the electrical probes 141 and contact pads on the quantum chip 150.

For example, in some embodiments, during a laser anneal process, a target Josephson junction of a given qubit is aligned to the center of the FOV of the microscope unit 130 using an automated pattern recognition process in which features of an image captured by the camera 132 are automatically aligned to corresponding features of a template image to ensure proper positioning of the target Josephson junction and associated contact pads. In particular, an alignment process is performed to ensure accurate registration between the contact pads of the target Josephson junction and the electrical probes 141 when performing an in-situ Josephson junction resistance measurement, or controlled-current tuning process. In addition, an alignment process is performed to ensure a proper alignment of the target Josephson junction and a laser spot pattern when performing a laser anneal operation.

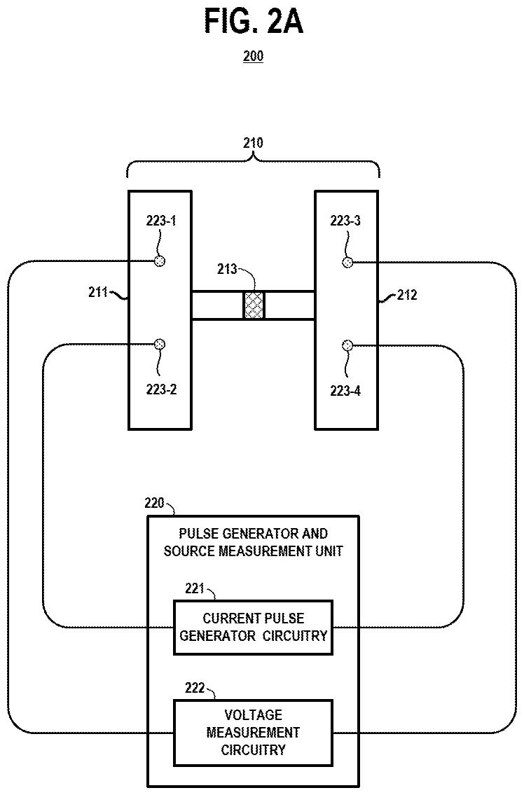

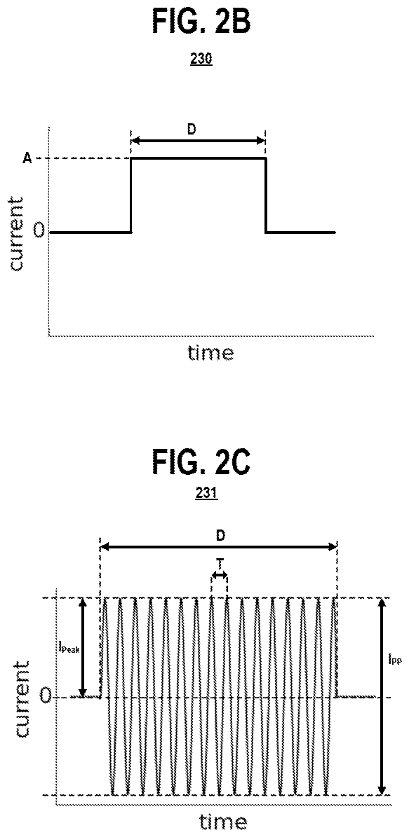

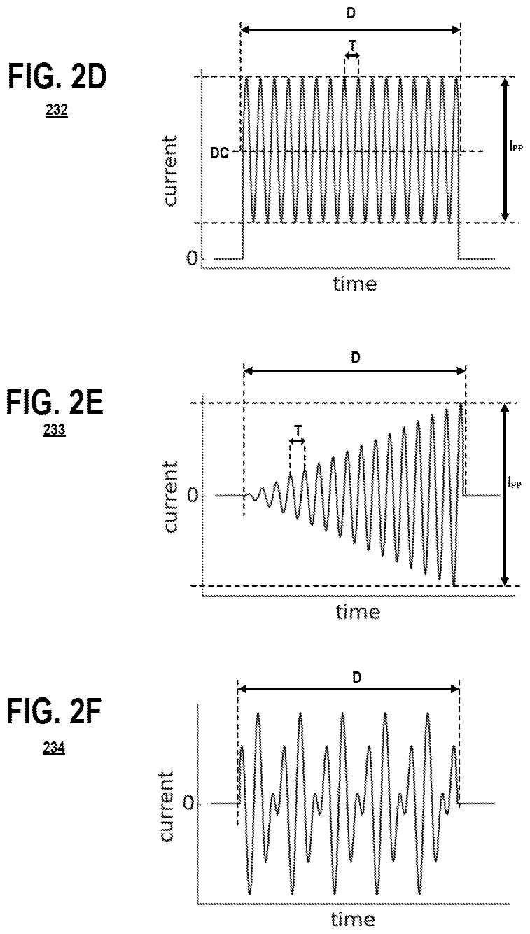

In some embodiments, the electrical probes 141 are configured to perform a 4-wire resistance measurement (or Kelvin resistance measurement) to more precisely measure the junction resistance of a Josephson junction. In general, a 4-wire (Kelvin) resistance measurement involves determining the resistance of a given Josephson junction by measuring a current (I) flow through the junction as well as a voltage (V) drop across the junction, and determining the junction resistance R_{J} from Ohm's Law, i.e., R_{J}=V/I. In addition, the electrical probes 141 are utilized for applying controlled tuning currents to Josephson junctions when performing a controlled-current tuning process. Essentially, the pulse generator and SMU 113 comprises a test instrument which combines a sourcing function (to precisely source voltage and current pulses/signals) and a measurement function (measure voltage or current) on the same group of probes. In this regard, the pulse generator and SMU 113 is configured to generate and measure voltage and/or currents to perform junction resistance measurement, and well as generate controlled current signals/pulses that are applied on the electrical probes 141 to perform controlled-current tuning operations. Exemplary embodiments for performing 4-wire (Kelvin) resistance measurement operations, and controlled-current tuning operations will be discussed in further detail below in conjunction with, e.g., FIG. 2.

In some embodiments, the electrical probes 141 comprise a probe card that is mechanically mounted in a fixed position in the prober unit 140. In some embodiments, an integration of the microscope unit 130 and the prober unit 140 is configured to ensure that a probing plane is displaced from a sample imaging plane by a preset amount, e.g., 70 microns, 80 microns, etc. In this configuration, the electrical probes 141 are fixedly displaced from the image plane, and the Z-position of the X-Y-Z stage 142 (with the quantum chip 150 mounted thereon) is moved into a default contact position to make electrical contact between the electrical probes 141 and target contact pads on the quantum chip 150, to perform junction resistance measurements and controlled-current tuning operations, under control of the prober control unit 114 and the pulse generator and SMU 113.

In some embodiments, the thermoelectric element 143 is utilized as a thermal control system (e.g., temperature-controlled wafer chuck system, or other suitable types of heating/cooling systems) that is configured to (i) heat the quantum chip 150 to perform a bulk thermal anneal operation for shifting the junction resistances of the tunnel junction devices of the quantum chip 150, and to (ii) cool the quantum chip 150 to desired temperature to perform junction resistance measurements and junction resistance tuning operations, as will be discussed in further detail below. In this regard, the X-Y-Z stage 142 may be temperature controlled to allow high-temperature anneals (e.g., bulk anneals) or low-temperature probing for low-noise electrical resistance measurements. For example, in some embodiments, a temperature-controlled wafer chuck system can be temperature controlled in a range of −60° C. to 300° C. The prober control unit 114 comprises a combination of hardware and software to control automated operations of the prober unit 140 (e.g., automated movement of X-Y-Z stage 142, heating/cooling of quantum chip 150 via the thermoelectric element 143, etc.).

In some embodiments, in order to image, electrically characterize, performing controlled-current tuning, and perform laser tuning of Josephson junctions, the X-Y-Z stage 142 is set at various positions such that these functions may be safely and effectively performed at various positions of the X-Y-Z stage., including a “contact position,” an “anneal position,” and a “safety position” to denote various positions of the X-Y-Z stage. The “contact position” refers to the position of the X-Y-Z stage 142 such that the sample (i.e., quantum chip 150) is in mechanical and electrical contact with the electrical probes 141. That is to say, the surface of the sample is substantially identical to the probing plane. In this “contact position” configuration, electrical characterization may take place, which typically involves a 4-wire (Kelvin) resistance measurement. Each tuning iteration will typically involve a junction resistance measurement, where the X-Y-Z stage 142 is brought into the “contact position” to perform a junction resistance measure.

The “anneal position” refers to the Z position of the X-Y-Z stage 142 such that the surface of the sample (i.e., quantum chip 150) is at the focal plane of the laser annealing beam. In an exemplary embodiment, at the “anneal position,” the surface of the sample (i.e., quantum chip 150) is substantially identical to the imaging plane, such that both imaging and annealing occurs at the same Z position of the X-Y-Z stage 142, or stated equivalently, the sample and laser beam may be both viewed in focus simultaneously by the imaging system. Additionally, at the “anneal position,” pattern recognition and corrective alignment may take place, such that the junction is correctly centered at the FOV prior to annealing. It is also at the anneal position which visual characterization, inspection, and the like, may be performed to determine whether the chip is physically suitable for use as a chip candidate. Nominally, the “anneal position” may be chosen to be a fixed difference from the “contact position,” which is herein defined as the “separation distance,” which may be, for example, 70 microns, 80 microns, etc., and may be selected by the operator as desired.

The “safety position” refers to a large displacement of the Z position of the X-Y-Z stage 142 such that the surface of the sample (i.e., quantum chip 150) is safely displaced from the “contact position” such that the tallest surface feature of the sample will not cross the probing plane, or stated equivalently, no feature on the sample intersects the probing plane. In this way, regardless of the X-position or Y-position that is chosen on the sample, the electrical probes 141 are not at risk of damage due to impact with any surface feature while the X-Y-Z stage 142 is in the “safety position.”

In an exemplary embodiment, the position of the electrical probes 141 (e.g., probe card) is fixed in the Z position, and the “separation distance” is selected to be 70 microns, that is, the “anneal position” is 70 microns below the “contact position.” Additionally, the “safety position” may be chosen (for example) to be 1000 microns or larger, or a value that is sufficiently larger than the height of any feature on the sample devices (e.g., quantum chip 150). When the apparatus is initialized, the relative positions of the sample plane, the probing plane, imaging plane and laser annealing plane are not known a priori, and any operation performed using the system 100 may exhibit, for example, image defocusing, poor electrical contact during probing, and/or poor annealing performance. Therefore, an initialization protocol can be performed to ensure that the contact position, anneal position, and safety position are well-defined positions.

In an exemplary embodiment, to define these positions, the X-Y-Z stage 142 may be programmed to move to a safe location, either on a test chip, an initialization chip, or the like, where a clean conducting surface (e.g., contact pads) is available under the probes. In this exemplary embodiment, a dedicated initialization chip with an array of conducting contact pads is available to safely contact the electrical probes 141. The X-Y-Z stage 142 is subsequently incremented (e.g., in 2-micron increments) in the Z position, towards the electrical probes 141, and the contact resistance is checked for each increment until a contact threshold is realized (e.g., 100 ohms, or another threshold as desired), which indicates successful contact between the sample and the probing plane, or equivalently, the sample plane and probing plane are co-located, and the X-Y-Z stage 142 is in the “contact position.” Subsequent to determining the contact position, the X-Y-Z stage 142 is lowered in the Z position by the desired 70 microns “separation distance,” such that the X-Y-Z stage 142 is in “alignment position.” However, it may be the case that the image focal plane is not yet at a substantially identical position as the sample surface. In this case, the microscope unit may be adjusted, either manually using a Z focus adjustment, or automatically (in the case where the microscope is mounted on its own X-Y-Z stage, and controlled by the imaging control unit 112), such that the imaging focal plane is made substantially identical to the sample plane. Using this protocol, the “anneal position” thus corresponds to the sample surface being in focus in the microscope unit 130, and both imaging and annealing may now occur at the “anneal position.”

In the case where electrical measurement is desired, reliable probing may subsequently be implemented by simply incrementing the Z position of the X-Y-Z stage 142 by 70 microns (i.e., the “separation distance”), or more, as some level of overtravel is desirable for robust electrical contact. Furthermore, a “safety position” may be defined, such that when moving between qubits, or other features on the quantum chip 150, the X-Y-Z stage 142 first moves to its safety position, then moves to the X and Y-position of the desired feature, then moves to either the “anneal position” for imaging/tuning, or to the “contact position” for electrical characterization. The exemplary initialization protocol described above may be generally implemented to ensure that stage motion, imaging, annealing, and electrical measurement may be safely and reliably performed. It is to be understood that in one or more embodiments, the above initialization protocol, as well as the various X-Y-Z stage 142 positions, are actively used in the operation and calibration of the system 100. In some embodiments, the laser focal plane may be engineered as an additional degree of freedom relative to the image focal plane, and the laser beam may be focused or defocused as desired.

In some embodiments, the prober unit 140 is housed or otherwise disposed within the optional environmental chamber to control an ambient environment during laser annealing, wherein different ambient environments impact the laser annealing progression differently. For example, in some embodiments, the system 100 may further comprise an environmental gas control system which is coupled to the environmental chamber and which is configured to inject a mixture of one or more gases into the environmental chamber to control the annealing environment. More specifically, in some embodiments, the environmental gas control system may comprise a gas dilution unit which is connected to a plurality of gas cylinders which store different gases (e.g., nitrogen, dry air, etc.), wherein the gas dilution unit can mix different gases at various concentrations and inject the mixed gases into the environmental chamber, as desired, to provide a given gas environment for laser annealing. In addition, the environmental gas control system comprises a vacuum system coupled to the environmental chamber to evacuate anneal gases from the chamber or otherwise evacuate air from the environmental chamber to perform laser annealing in a vacuum atmosphere.

As noted above, in some embodiments, the various functions of the laser unit 120, the microscope unit 130, and the prober unit 140 are automatically controlled by the control system 110. In some embodiments, the laser annealing control unit 111, the imaging control unit 112, the pulse generator and SMU 113, and the prober control unit 114, comprise respective hardware interfaces for interfacing with the laser unit 120, the microscope unit 130, and the prober unit 140, as needed, to generate and apply control signals to components of such units 120, 130, and 140, and to receive and process signals (e.g., data, measurements, feedback controls signals, etc.) received from such units 120, 130, and 140. The data processing system 115 comprises one or more processors that execute software programs/routines to control the process and execution flow of the laser tuning operations, controlled-current tuning operations, junction resistance measurement operations, and prober unit operations, by processing data received from the control units 111, 112, 113, and 114 (e.g., to perform automated pattern recognition for active alignments, perform junction resistance measurement computations, etc.), and generating and outputting control signals to cause the control units 111, 112, 113, and 114 to control the operations of the laser unit 120, the microscope unit 130, and the prober unit 140 in a coordinated manner, when performing laser tuning operations, controlled-current tuning operations, and in-situ junction resistance measurements, as discussed herein.

For example, in some embodiments, the laser annealing control unit 111 is configured to control operation of components of the laser unit 120, such as the laser source 121 and the laser power control block 123, to adjust the power level of the laser beam output from the laser unit 120. In addition, the laser annealing control unit 111 is configured to control the operation of components of the microscope unit 130 for laser annealing operations. For example, the laser annealing control unit 111 is configured to control the operation of the laser beam shutter 133 to control the duration of laser exposure when laser tuning a given Josephson junction. Further, in some embodiments, the laser annealing control unit 111 is configured to control the laser beam shaper 135, e.g., to switch the diffractive beam splitter settings and corresponding laser illumination patterns.

Further, in some embodiments, the imaging control unit 112 is configured to control the operation of the light source 131, the camera 132, and one or more of the optical components 136 (e.g., tube lens) that make up the image path of the microscope unit 130. For example, the imaging control unit 112 can generate camera control signals to cause the camera 132 to capture images within the FOV of the microscope unit 130 and send images to the imaging control unit 112. The imaging control unit 112 can be configured to preprocess the image data into a suitable format for processing by the data processing system 115 to perform automated pattern recognition functions to perform laser alignment and electrical probe alignment operations as discussed herein.

Moreover, as discussed above, the pulse generator and SMU 113 and the prober control unit 114 are configured to control operations of the prober unit 140 to perform automated operations such as, e.g., adjusting the position of the X-Y-Z stage 142 for different operations, measuring junction resistances of Josephson junctions, and performing controlled-current tuning operations on Josepson junctions, etc. As noted above, the pulse generator and SMU 113 comprises current/voltage generation and measurement circuitry, which is coupled to the electrical probes 141. When performing junction resistance measurements, the pulse generator and SMU 113 is can be configured to measure current that flows through a Josephson junction as a result of applying a test voltage to the electrical probes, as well as measure a voltage across the Josephson junction. The measured currents and voltages can be digitized and sent to the data processing system 115 for computing junction resistances.

In some embodiments, the data processing system 115 executes a tuning calibration process to configure the system 100 to perform laser tuning calibration operations on test Josephson junctions of representative hardware. In some embodiments, the data processing system 115 executes a calibration process by performing trial laser annealing operations on test Josephson junctions of representative hardware, using different combinations of laser anneal power, and anneal time, and (optionally) laser beam illumination patterns, to generate laser tuning calibration data which is stored in the database of tuning calibration data 116. The laser tuning calibration data can be obtained by performing a calibration process on representative hardware which, in some embodiments, can be dummy Josephson junctions that reside on the same quantum chip to be tuned, and in other embodiments, can be Josephson junctions of qubits that are formed on a sister chiplet from the same fabrication process.

The laser tuning calibration data is analyzed using statistical methods to fit the laser tuning calibration data to tuning curves, wherein the tuning curves are utilized to determine tuning rates and maximum tuning ranges for Josephson junctions under different laser anneal powers and anneal times. The tuning curves are utilized by the data processing system 115 to select a target combination of anneal power and annual time, as desired, for a target tuning rate and maximum tuning range for laser annealing Josephson junctions of the given quantum chip, post fabrication. In some embodiments, the tuning curves are used to predict an initial laser anneal operation (initial shot) for tuning a given Josephson junction to a certain target (e.g., 50% to target) on a first shot. The calibration process ensures a smooth and rapid approach to a target tuning for a given Josephson junction, while mitigating risk of both undershooting and overshooting the tuning.

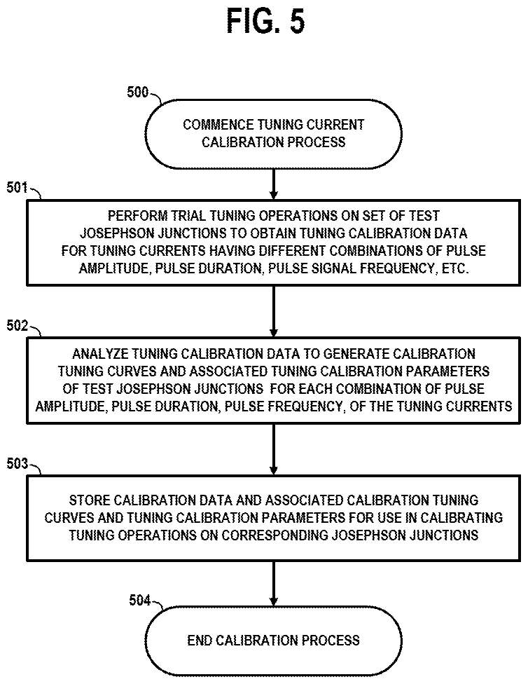

Moreover, in some embodiments, the data processing system 115 executes a calibration process by performing trial controlled-current tuning operations on test Josephson junctions of representative hardware, for controlled tuning currents having different combinations of pulse amplitude, pulse duration, pulse signal frequency, etc. to obtain controlled-current tuning calibration data which is persistently stored in the database of tuning calibration data 116. The controlled-current tuning calibration data can be subsequently accessed and utilized to configure controlled-current tuning operations by selecting tuning currents for precision junction resistance tuning. As explained in further detail below in conjunction with FIGS. 5, 6, and 7, the trial controlled-current tuning operations can be performed on a group of test superconducting tunnel junction devices by applying currents with different combinations current magnitudes and durations to tune junction resistances of the test superconducting tunnel junction devices, determining junction resistance shifts of the first superconducting tunnel junction devices as a result of the tuning calibration operations, and utilizing the determined junction resistance shifts of the test superconducting tunnel junction devices to determine tuning calibration data for configuring tuning currents to perform tuning operations on superconducting tunnel junction devices which have similar tuning characteristics as the test superconducting tunnel junction devices.

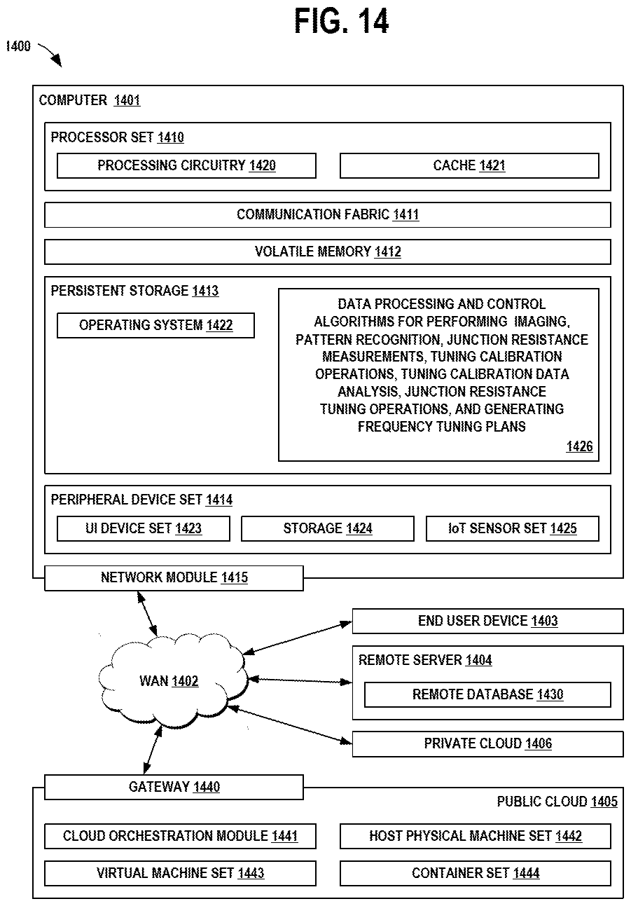

In some embodiments, the control system 110 is implemented using any suitable computing system architecture which is configured to implement methods to support the automated control processes as described herein by executing computer readable program instructions that are embodied on a computer program product which includes a computer readable storage medium (or media) having such computer readable program instructions thereon for causing a processor to perform control methods as discussed herein. An exemplary architecture of a computing environment for implementing a control system that is configured to control junction resistance measurement operation and junction resistance tuning operations, will be discussed in further detail below in conjunction with FIG. 14. It is to be appreciated that the exemplary system 100 of FIG. 1 can be used to perform exemplary laser and controlled-current calibration and tuning methods, and other methods, such as those discussed in detail below in conjunction with, e.g., FIGS. 2A-13B.

FIG. 2A schematically illustrates a method for measuring and tuning a junction resistance of a Josephson junction, according to an exemplary embodiment of the disclosure. In particular, FIG. 2A schematically illustrates a method 200 for utilizing a 4-probe configuration to perform a 4-wire resistance measurement (or Kelvin resistance measurement) to measure the junction resistance of a Josephson junction, as well as applying a controlled current to shift the junction resistance of the Josephson junction. In some embodiments, FIG. 2A schematically illustrates an exemplary embodiment and configuration of the pulse generator and SMU 113 and the prober unit 140 of FIG. 1 to measure and tune a junction resistance of a Josephson junction of a superconducting transmon qubit.

In particular, FIG. 2A schematically illustrates a superconducting qubit 210, a pulse generator and source measurement unit 220, and a 4-wire electrical probe configuration which comprises a first probe 223-1, a second probe 223-2, a third probe 223-3, and a fourth probe 223-4 (which are schematically illustrated in FIG. 2A as circles that represent probe tips of the corresponding electrical probes). The pulse generator and source measurement unit 220 comprises current pulse generator circuitry 221 and a voltage measurement circuitry 222. The superconducting qubit 210 comprises a transmon qubit which comprises a first superconducting pad 211, a second superconducting pad 212, and a Josephson junction 213 coupled to, and disposed between, the first and second superconducting pads 211 and 212. The first and second superconducting pads 211 and 212 comprise electrodes of a coplanar capacitor structure of the superconducting qubit 210. The Josephson junction 213 functions as a non-linear inductor which, when shunted with the capacitor formed by the first and second superconducting pads 211 and 212, forms an anharmonic LC oscillator with individually addressable energy levels of computational basis states (e.g., two lowest energy level corresponding to the ground state |0> and the first excited state |1>) and a given transition frequency f₀₁.

As schematically illustrated in FIG. 2A, the probe tips of the first and second electrical probes 223-1 and 223-2 are aligned and in contact with the first superconducting pad 211 of the superconducting qubit 210, and the probe tips of the third and fourth electrical probes 223-3 and 223-4 are aligned and in contact with the second superconducting pad 212 of the superconducting qubit 210. In this embodiment, the first and second superconducting pads 211 and 212 of the superconducting qubit 210 serve as the contact pads of the Josephson junction 213 on which the probe tips of the electrical probes 223-1, 223-2, 223-3, and 223-4 are landed to perform junction resistance measurement and tuning operations. Further, as schematically shown in FIG. 2A, the first and third electrical probes 223-1 and 223-3 are electrically connected to the voltage measurement circuitry 222, and the second and fourth electrical probes 223-2 and 223-4 are electrically connected to the current pulse generator circuitry 221.

In some embodiments, the pulse generator and source measurement unit 220 is configured to perform a 4-wire (Kelvin) resistance measurement to measure the junction resistance of the Josephson junction 213 by a process which comprises (i) utilizing the current pulse generator circuitry 221 to generate and output a current pulse (e.g., DC pulse) to cause a current to flow from the second electrical probe 223-2 to the fourth electrical probe 223-4 (or vice versa) through the Josephson junction 213, (ii) utilizing the voltage measurement circuitry 222 and the first and third electrical probes 223-1 and 223-3 to detect and measure a voltage drop (V) across the Josephson junction 213 as a result of the current (I) flowing through the Josephson junction 213, and (iii) determining a junction resistance Rₙ from Ohm's Law, i.e., Rₙ=V/I. In some embodiments, the current pulse that is used to perform a junction resistance measurement comprises a pulse amplitude and duration which is sufficient to perform a 4-wire junction resistance measurement, while not causing a shift in the junction resistance as a result of the resistance measurement operation.

Furthermore, in some embodiments, the pulse generator and source measurement unit 220 is configured to perform a controlled-current tuning operation by a process which comprises utilizing the current pulse generator circuitry 221 to generate and output (i) a controlled DC tuning current with a given amplitude and duration, or (ii) a controlled AC tuning current with a given peak amplitude, frequency, duration, DC offset, etc., to cause the controlled tuning current to flow from the second electrical probe 223-2 and to the fourth electrical probe 223-4 (or vice versa) through the Josephson junction 213, which is sufficient to change the junction resistance Rₙ of the Josephson junction 213. In some embodiments, during the controlled-current tuning operation, the pulse generator and source measurement unit 220 is configured to (i) utilize the voltage measurement circuitry 222 and the first and third electrical probes 223-1 and 223-3 to detect and measure a voltage drop (V) across the Josephson junction 213 as a result of the tuning current flowing through the Josephson junction 213, and (ii) determine and track a change in the junction resistance Rₙ as the tuning current is applied.

In some embodiments, the tuning current generated by the current pulse generator circuitry 221 for performing a controlled-current tuning operation comprises a DC pulse with a given pulse amplitude and pulse duration that is sufficient to shift the junction resistance of the Josephson junction to a target junction resistance. In some embodiments, the tuning current generated by the current pulse generator circuitry 221 for performing the controlled-current tuning operation comprises an AC pulse signal with a given pulse frequency, peak amplitude, DC offset, etc. The use of an AC tuning current can help to minimize electromigration and prevent breakdown of the Josephson junction 213.

It is to be appreciated that as schematically illustrated in FIG. 2A, the exemplary 4-probe configuration allows the same probe alignment and contact configuration to be used for measuring the junction resistance of a Josephson junction as well as applying a controlled current to tune the junction resistance of the Josephson junction. Moreover, the 4-probe configuration allows a junction resistance measurement operation to be performed concurrently with a controlled-current tuning operation to track the change in junction resistance and determine when the junction resistance reaches a target junction resistance, in which case the tuning current can be terminated. In other embodiments, the junction resistance measurements and controlled-current tuning operations are performed separately, which allows the device junction to cool down after performing a controlled-current tuning operation before measuring the junction resistance.

FIGS. 2B, 2C, 2D, 2E, and 2F illustrate profiles of tuning currents that can be utilized for tuning a junction resistance of a Josephson junction, according to exemplary embodiments of the disclosure. In some embodiments, FIGS. 2B, 2C, 2D, 2E, and 2F illustrate profiles of tuning currents that can be selectively generated by the current pulse generator circuitry 221 of FIG. 2A. FIG. 2B illustrates an exemplary DC tuning current pulse 230 having a given pulse amplitude A, and pulse duration D (or pulse width). The pulse amplitude A and pulse duration D can be configured, as desired, to cause a resistance shift of the junction resistance of a Josephson junction. It is to be noted that a DC current pulse with a relatively low amplitude can be utilized to perform in situ 4-wire junction resistance measurements, as discussed herein.

Next, FIGS. 2C, 2D, 2E, and 2F illustrate different AC tuning current pulses that can be selectively generated by the current pulse generator circuitry 221 of FIG. 2A to perform controlled-current tuning operations. In particular, FIG. 2C illustrates an exemplary AC tuning current pulse 231 with a square-shaped pulse envelope, and having a given frequency (1/T), a peak-to-peak current I_{PP} (or peak current I_{P}), and a pulse duration D (or number of cycles), with no DC offset. FIG. 2D illustrates an exemplary AC tuning current pulse 232 which is similar to the AC tuning current pulse 231, but with an added DC offset. FIG. 2E illustrates an exemplary AC tuning current pulse 233 with a triangular-shaped pulse envelope. The AC tuning current pulse 233 has a given frequency (1/T), and a monotonically increasing a peak-to-peak amplitude which increases from zero to a maximum peak-to-peak current I_{PP}, over a pulse duration D (or number of cycles), with no DC offset. Next, FIG. 2F illustrates an exemplary AC tuning current pulse 234 variable shaped pulse envelope which is generated as a result in combining multiple AC frequencies in the same pulse. The AC tuning current pulse 234 has a varying peak-to-peak current I_{PP}, over a pulse duration D, with no DC offset. The various parameters (e.g., amplitudes, durations, frequencies, pulse-shapes, DC offsets, etc.) of the exemplary tuning currents shown in FIGS. 2B-2F can be varied to generate controlled tuning current pulses with different profiles for performing controlled-current tuning of Josephson junctions.

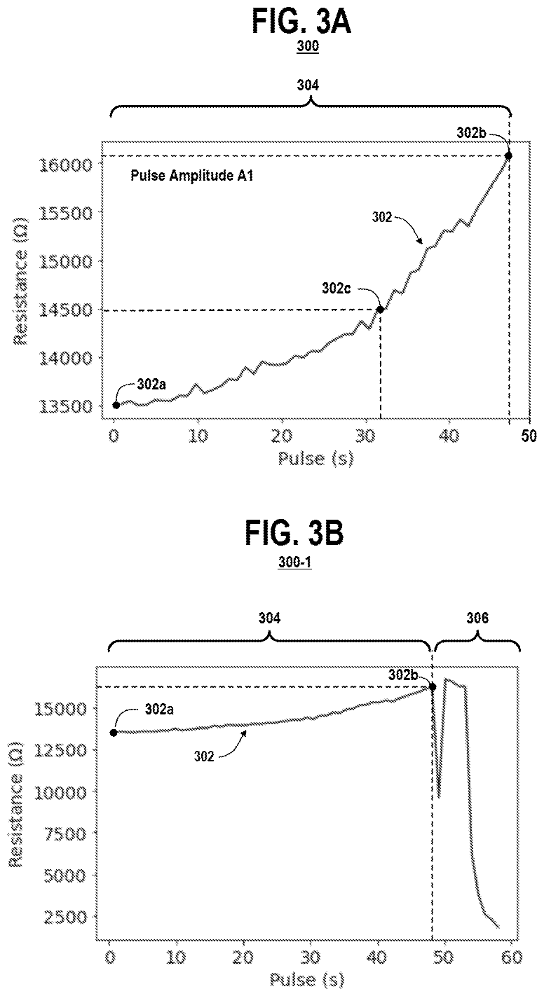

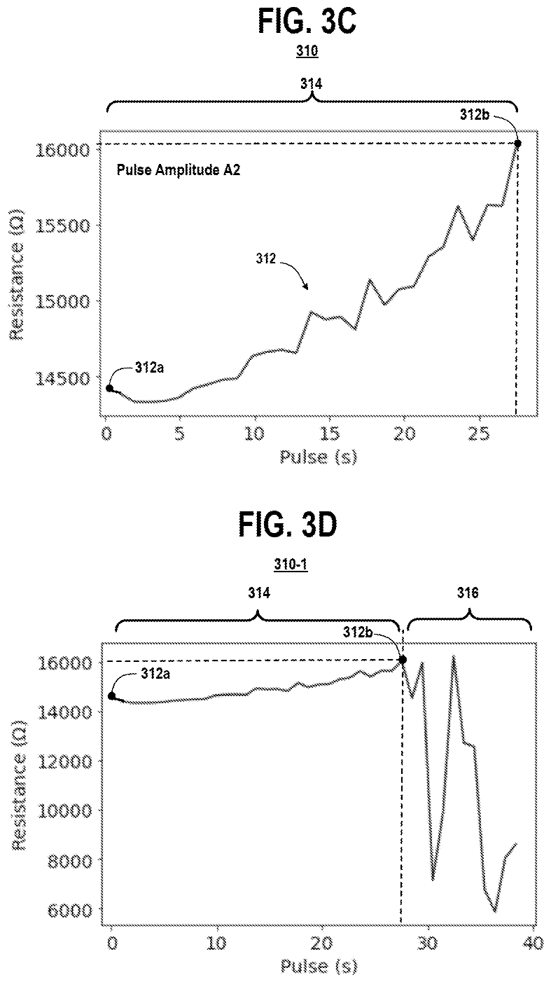

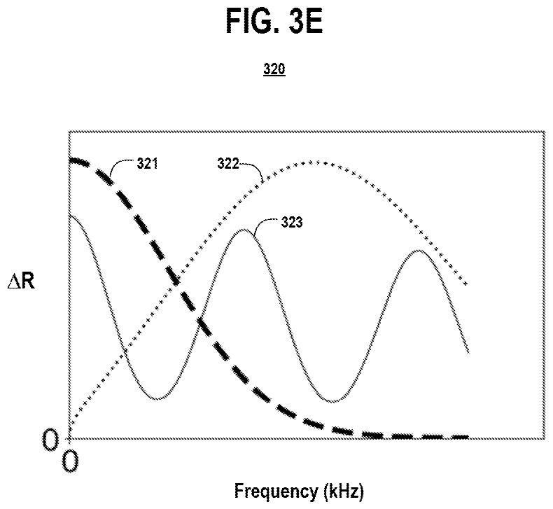

FIGS. 3A, 3B, 3C, 3D, and 3E depict graphs of tuning curves for tuning junction resistances of Josephson junctions, according to exemplary embodiments of the disclosure. In particular, FIGS. 3A, 3B, 3C, and 3D depict graphs of tuning curves for tuning junction resistances of Josephson junctions using DC current pulses with controlled pulse amplitude and pulse durations. For example, FIGS. 3A and 3B illustrate respective graphs 300 and 300-1 of an exemplary tuning curve 302, which represents a junction resistance in Ohms (Y-axis) of a first Josephson junction as a function of pulse duration in seconds (s) (X-axis) for a given DC tuning current pulse applied to the first Josephson junction, having a first pulse amplitude A1 (e.g., A1=1.0 microamp). FIGS. 3C and 3D illustrate respective graphs 310 and 310-1 of an exemplary tuning curve 312, which represents a junction resistance in Ohms (Y-axis) of a second Josephson junction as a function of pulse duration in seconds (s) (X-axis) for a given DC tuning current pulse applied to the second Josephson junction, having a second pulse amplitude A2, where A2>A1.

FIGS. 3A and 3B illustrates a positive tuning region 304 of the exemplary tuning curve 302 in which a junction resistance of the first Josephson junction increases from an initial junction resistance Rᵢₙᵢₜᵢₐₗ (which is represented at point 302a) to a maximum junction resistance (which is represented at point 302b), as a result of applying the DC tuning current pulse of amplitude A1 for a duration of about 48 second. In addition, FIG. 3B illustrates a breakdown region 306 which starts to occur after about 48 seconds, wherein the junction resistance becomes erratic and eventually decreases due to breakdown of the first Josephson junction as a result of the relatively long duration of the DC tuning current pulse. In other words, the point 302b on the tuning curve 302 represents a maximum positive tuning range (or maximum positive resistance shift) for the exemplary tuning curve 302. In addition, FIG. 3A illustrates that the positive tuning region 304 comprises a tuning rate which can be derived based on a slope of the tuning curve 302 in the positive tuning region 304.

FIG. 3A further illustrates an exemplary target junction resistance R_{target} (which is represented at point 302c) which provides an amount of junction resistance shift (ΔR) % that can be achieved for the given DC tuning pulse with the pulse amplitude of A1 with a pulse duration of about 32 seconds). It is to be noted that term ΔR denotes a difference between an initial junction resistance (denoted Rᵢₙᵢₜᵢₐₗ) of given Josephson junction before applying a tuning current, and a current junction resistance (denoted R_{current}) of the given Josephson junction after applying a tuning current to shift the junction resistance of the given Josephson junction, i.e., ΔR=R_{current}−Rᵢₙᵢₜᵢₐₗ. In this regard, a “resistance shift percentage” can be determined as

$$Δ R \% = \frac{Δ R}{{R}_{initial}} \times 100 \% = \frac{{R}_{current} - {R}_{initial}}{{R}_{initial}} \times 100 \% .$$

It is to be noted that the term “current junction resistance” as used herein and in conjunction with the notation R_{current} is meant to denote a junction resistance measured in the sense of occurring in or existing at a present time, or a most recently measured junction resistance.

Moreover, the term ΔR_{target}=R_{target}−Rᵢₙᵢₜᵢₐₗ, wherein the target junction resistance R_{target} denotes target junction resistance of a given superconducting tunnel junction device (e.g., Josephson junction) which desired to be achieved. In the exemplary embodiment of FIG. 3A, the assuming Rᵢₙᵢₜᵢₐₗ=13.5 kiloohms (kΩ) and R_{target}=14.5 kΩ, then ΔR_{target}=R_{target}−Rᵢₙᵢₜᵢₐₗ=14.5 kΩ−13.5 kΩ=1.0 kΩ. Further,

$$Δ {R}_{target} \% = \frac{Δ {R}_{target}}{{R}_{initial}} \times 100 \% = \frac{1. k Ω}{13.5 k Ω} \times 100 \% = 7.4 \% .$$

In this regard, the tuning curve 302 can be utilized to estimate that a junction resistance shift of ΔR_{target}%≅7.0% can be achieved to tune the junction resistance of a given Josephson junction by applying a DC tuning current pulse with the pulse amplitude A1 for a pulse duration of about 30 seconds.

FIGS. 3C and 3D illustrates a positive tuning region 314 of the exemplary tuning curve 312 in which a junction resistance of the second Josephson junction increases from an initial junction resistance Rᵢₙᵢₜᵢₐₗ (which is represented at point 312a) to a maximum junction resistance (which is represented at point 312b), as a result of applying the DC tuning current pulse of amplitude A2 (A2>A1) for a pulse duration of about 28 seconds. In addition, FIG. 3D illustrates a breakdown region 316 which starts to occur after about 28 seconds, wherein the junction resistance become erratic and eventually decreases due to breakdown of the second Josephson junction as a result of the relative long duration of the DC tuning current pulse. In other words, the point 312b on the tuning curve 312 represents a maximum positive tuning range (or maximum positive resistance shift) for the exemplary tuning curve 312. In addition, FIG. 3C illustrates that the positive tuning region 314 comprises a tuning rate which can be derived based on a slope of the tuning curve 312 in the positive tuning region 314.

Next, FIG. 3E is a graph 320 which shows tuning curves 321, 322, and 323 of junction resistance shift (ΔR) (Y-axis) as a function of frequency in kilohertz (X-axis). FIG. 3E shows that the junction resistance shifts (ΔR) of a Josephson junction can exhibit different levels of response as a function of the AC frequency of the applied tuning current pulse. For example, the tuning curve 321 illustrates that the junction resistance shift (ΔR) of a Josephson junction can have a relatively large response at DC, with decreasing responses at increasing frequency, and no response at large frequencies. In some embodiments, controlled-current tuning of such a Josephson junction would be performed using a DC pulse, as described above in FIG. 2B. Next, the tuning curve 322 illustrates that the junction resistance shift (ΔR) of a Josephson junction can have essentially no response at DC, and a relatively large response at some AC frequencies. In some embodiments, controlled-current tuning of such a Josephson junction would be performed using an AC pulse, as described above in FIGS. 2C and 2E. The tuning curve 323 illustrates that the junction resistance shift (ΔR) of a Josephson junction can have large responses at DC and at different multiple AC frequencies. In some embodiments, controlled-current tuning of such a junction would be performed using pulses comprising DC and/or multiple AC frequencies, as described above in FIGS. 2D and 2F. As explained in further detail below, controlled-current tuning calibration operations can be performed on test Josephson junctions with different profiles of DC and AC current pulses to determine optimal parameters of tuning current for performing controlled-current tuning operations.

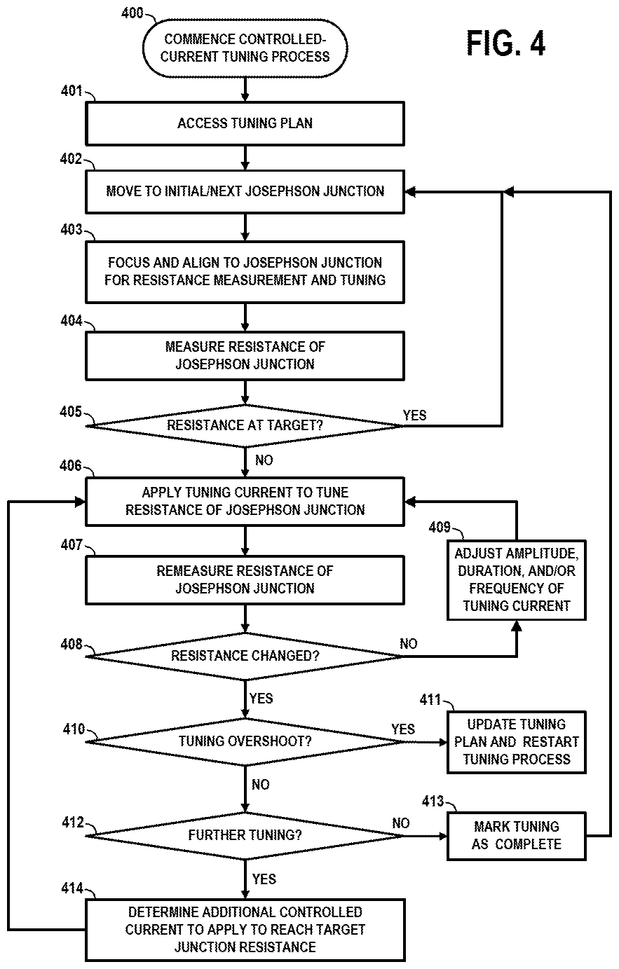

FIG. 4 illustrates a flow diagram of a method for tuning junction resistances of Josephson junctions, according to an exemplary embodiment of the disclosure. In some embodiments, FIG. 4 illustrates an automated controlled-current tuning process, which can be performed using the system 100 of FIG. 1, to tune Josephson junctions to respective R_{target} values and thereby tune superconducting qubits in a qubit lattice on a quantum chip to respective target transition frequencies as specified by a frequency tuning plan. For example, a quantum chip is placed on the X-Y-Z stage 142 of the prober unit 140, and the control system 110 commences an automated controlled-current tuning process (block 400). The quantum chip comprises a plurality of superconducting qubits arranged in a given qubit lattice. The controlled-current tuning process accesses a frequency tuning plan generated for the given qubit lattice (block 401). In some embodiments, the frequency tuning plan specifies respective R_{target} values for the Josephson junctions, possibly tuning calibration parameters for determining suitable pulse durations and pulse amplitudes of tuning currents to be used for tuning junction resistances of respective Josephson junctions of the superconducting qubits.

The automated controlled-current tuning process selects an initial Josephson junction of an initial superconducting qubit in the lattice and moves to the selected Josephson junction (block 402). In particular, the control system 110 moves the X-Y-Z stage 142 to place the initial Josephson junction into the FOV of the microscope unit 130. The controlled-current tuning process initiates control operations to cause the microscope unit and the probe unit to perform a focus and alignment process to ensure a proper focus to the focal plane and proper alignment of the target Josephson junction within the FOV of the microscope unit 130 for the purpose of contacting the electrical probes to the contact pads for the Josephson junction to perform junction resistance measurement and tuning operations (block 403). The focus ensures that the sample plane (e.g., the plane which contains the target Josephson junction) is at the focal plane (i.e., plane of focus) of the objective lens 137. The focus can be adjusted by adjusting the Z position of the X-Y-Z stage 142. The alignment to the Josephson junction can be performed using a machine learning pattern recognition process to align the Josephson junction to the center of the FOV.

Next, the controlled-current tuning process proceeds to measure the junction resistance of the target Josephson junction (block 404). In particular, the controlled-current tuning process measures an initial junction resistance Rᵢₙᵢₜᵢₐₗ of the Josephson junction. In some embodiments, the electrical probes 141 are landed on the contact pads with a fixed displacement distance and overdrive to ensure proper contact (e.g., a stable, low resistance contact). In some embodiments, the electrical probes 141 are vertically moved downward to contact the tips of the electrical probes 141 to the contact pads on the quantum chip. In other embodiments, the positions of the electrical probes 141 remain fixed, and the Z position of the X-Y-Z stage 142 is moved upward so that the contact pads on the quantum chip 140 are moved into contact with the tips of the electrical probes 141.

In some embodiments, a junction resistance measurement is performed using a 4-wire (Kelvin) probe resistance measurement operation, such as describe above in conjunction with FIG. 2A, whereby a constant current (DC current pulse) is passed through the Josephson junction, and a resulting voltage across the Josephson junction is measured, and the junction resistance is determined based on the magnitude of the constant current and the measured voltage. In some or other embodiments, the junction resistance is determined using a 4-wire (Kelvin) probe resistance measurement operation, whereby a constant voltage is sourced across the Josephson junction, and the resulting current is measured, and the junction resistance is determined based on the magnitude of the constant voltage and the measured current. Moreover, in some embodiments, contact resistance and contact stability checks are initially performed, prior to performing the junction resistance measurement, to ensure that the contact resistance is below a given threshold, and to ensure that the contact between the electrical probe and the contact pads of the Josephson junction and stable and not intermittent.

Next, a determination is made as to whether the junction resistance of the Josephson junction is at or near the specified target resistance (block 405). For example, in some embodiments, the junction resistance of the given Josephson junction will be deemed to be at or near the target junction resistance R_{target} if the currently measured junction resistance R_{current} is within some specified threshold percentage of the target junction resistance R_{target}, i.e.,

$$\frac{\vert {R}_{target} - {R}_{current} \vert}{{R}_{target}} \leq x ( e . g . , x = 0.003 ( or 0.3 \% ) ) .$$

When the given Josephson junction has a junction resistance which deemed to be at or near its target junction resistance R_{target}, it is assumed that the corresponding superconducting qubit has been tuned successfully and within a corresponding bound of precision to its respective target transition frequency.

In this regard, if the junction resistance of the Josephson junction is determined to be at or near the specified target resistance (affirmative determination in block 405), the controlled-current tuning process selects a next Josephson junction of a next superconducting qubit to be tuned (return to block 402). On the other hand, if the junction resistance of the Josephson junction is determined to not be at or near the specified target resistance (negative determination in block 405), the controlled-current tuning process will proceed to apply a controlled tuning current to the given Josephson junction to tune the junction resistance, e.g., shift the junction resistance towards the target junction resistance of the given Josephson junction (block 406). In some embodiments, the controlled-current tuning operation can be implemented without using pre-determined tuning calibration data, whereby the parameters of a controlled current pulse (DC tuning current or AC tuning current) to be applied to the Josephson junction are estimated based at least in part on a determined difference between the measured junction resistance and the target junction resistance of the given Josephson junction. In other embodiments, a default controlled tuning current (e.g., DC tuning current pulse, AC tuning current pulse) can be initially applied to shift the junction resistance towards the target resistance.

After applying the initial controlled tuning current, the controlled-current tuning process proceeds to remeasure the junction resistance of the given Josephson junction (block 407). This process can be performed as discussed above, by applying a low magnitude DC current to the given Josephson junction and measuring a resulting voltage drop across the Josephson junction to determine the junction resistance. If the controlled-current tuning process determines that the junction resistance of the given Josephson junction has not changed at all, or has changed a very small amount (negative determination in block 408) the controlled-current tuning process will proceed to adjust one or more the controlled tuning current parameters (e.g., amplitude, duration, frequency, pulse envelope, etc.) of the controlled tuning current (block 409) an applying the controlled tuning current with the adjusted parameter(s) to the given Josephson junction to tune the junction resistance, e.g., shift the junction resistance towards the target junction resistance of the given Josephson junction (return to block 406).

On the other hand, if the controlled-current tuning process determines that the junction resistance of the given Josephson junction has changed (affirmative determination in block 408), the controlled-current tuning process will determine whether or not the remeasured junction resistance has exceeded the target junction resistance resulting in an undesired tuning overshoot (block 410). If the controlled-current tuning process determines that a tuning overshoot has resulted for the given Josephson junction (affirmative determination in block 410), the controlled-current tuning process can be paused, to allow a new or updated frequency tuning plan to be generated which takes into account the tuning overshoot of the given Josephson junction (block 411), which case the controlled-current tuning process can be restarted using the new or updated frequency tuning plan.

On the other hand, if the controlled-current tuning process determines that a tuning overshoot has not resulted for the given Josephson junction (negative determination in block 410), the controlled-current tuning process will determine if further resistance tuning is needed to reach the target junction resistance of the given Josephson junction (block 412). For example, in some embodiments, as noted above, a determination is made as to whether the remeasured junction resistance R_{current} is at or near the target junction resistance R_{target} within some specified threshold percentage (e.g., ±0.3%) of the target junction resistance R_{target}. If the controlled-current tuning process determines that no further resistance tuning is needed to reach the target junction resistance of the given Josephson junction (negative determination in block 412), the tuning for the given Josephson junction will be marked complete (block 413), and the controlled-current tuning process selects a next Josephson junction of a next superconducting qubit to be tuned (return to block 402) and repeats the controlled-current tuning process for the next Josephson junction.

On the other hand, if the controlled-current tuning process determines that further resistance tuning is needed to reach the target junction resistance of the given Josephson junction (affirmative determination in block 412), the controlled-current tuning process will proceed to estimate an additional amount of the controlled tuning current (e.g., same tuning current parameters, with adjusted duration) to apply to the Josephson junction, which may be sufficient to cause a further shift in the junction resistance of the given Josephson junction to the target junction resistance (block 414). The controlled-current tuning process will then proceed to apply the additional tuning current to the Josephson junction to shift the junction resistance to the target junction resistance (return to block 406), and the process flow (blocks 407-414) is repeated for the given Josephson junction.

While FIG. 4 illustrates an exemplary embodiment in which the controlled tuning current parameters (e.g., pulse amplitudes, pulse durations, etc.) are determined/estimated and adjusted during the controlled-current tuning process, as needed, without the use of predetermined controlled tuning current calibration data, other exemplary embodiment of the disclosure include tuning calibration techniques that are configured to generate tuning calibration data for, e.g., DC tuning current pulses with different combinations of pulse durations and pulse amplitudes and/or AC tuning current signals with different combinations of pulse frequencies and peak-to-peak amplitudes, to thereby enable proper selection of current tuning parameters for precise junction resistance tuning of Josephson junctions. In some embodiments, the exemplary calibration techniques are configured to obtain tuning calibration data by performing trial tuning operations on representative hardware comprising Josephson junction (e.g., qubits with Josephson junctions), and utilize the tuning calibration data to determine DC and/or AC current tuning calibration parameters including, e.g., tuning rates and maximum tuning ranges for various combinations of different pulse amplitudes, pulse durations, pulse frequencies, etc.

For example, FIG. 5 illustrates a flow diagram of a calibration process for obtaining tuning current calibration data for use in controlled-current tuning of the junction resistances of Josephson junctions, according to an exemplary embodiment of the disclosure. In some embodiments, FIG. 5 illustrates a calibration process that can be performed using the system 100 of FIG. 1 with the control system 110 executing a calibration algorithm. Referring to FIG. 5, a quantum chip is placed on the X-Y-Z stage 142 of the prober unit 140, and the control system 110 commences an automated calibration process (block 500). In some embodiments, the quantum chip comprises a set of test Josephson junctions which are representative of actual Josephson junctions that are to be tuned (via current pulses) using the calibration data obtained from the calibration process. In some embodiments, the quantum chip is a test chip, e.g., a sister chiplet from a same wafer having quantum devices and Josephson junctions that were fabricated using the same fabrication processes (e.g., junction evaporation process) as the Josephson junctions on the actual quantum chip. In this regard, the Josephson junctions on the test chip (e.g., sister chiplet) are deemed to correspond to the Josephson junctions on the actual chip which are to be tuned using DC and/or AC tuning currents and associated tuning operations that are configured by the prober control unit 114 using the calibration data obtained from the calibration operations performed on the test Josephson junctions on the test chip, since the test Josephson junctions and the actual Josephson junctions are fabricated using the same or similar processes. In this regard, the test Josephson junctions are assumed to have the same, or substantially the same, or similar tuning characteristics as the Josephson junctions on the actual chip which are to be tuned using tuning currents and associated tuning operations that are configured using the calibration data obtained from the calibration operations performed on the test Josephson junctions on the test chip.

In other embodiments, the calibration process may be implemented using a collection of test Josephson junction devices that reside on the same quantum chip which has the actual Josephson junctions that are to be tuned. For example, the collection of Josephson junctions can be a dedicated test array of Josephson junctions that are formed on the quantum chip and located, e.g., in the kerf of the quantum chip. In this regard, the collection of test Josephson junctions on the quantum chip correspond to the actual Josephson junctions on the same quantum chip, which are to be tuned using DC or AC tuning currents that are configured using the calibration data obtained from the calibration operations performed on the test Josephson junctions on the same quantum chip. Since the collection of test Josephson junctions and the actual Josephson junctions (residing on the same quantum chip) are fabricated using the same fabrication processes, the test Josephson junctions and actual Josephson junctions (to be tuned) will have the same, or substantially the same, or similar tuning characteristics.

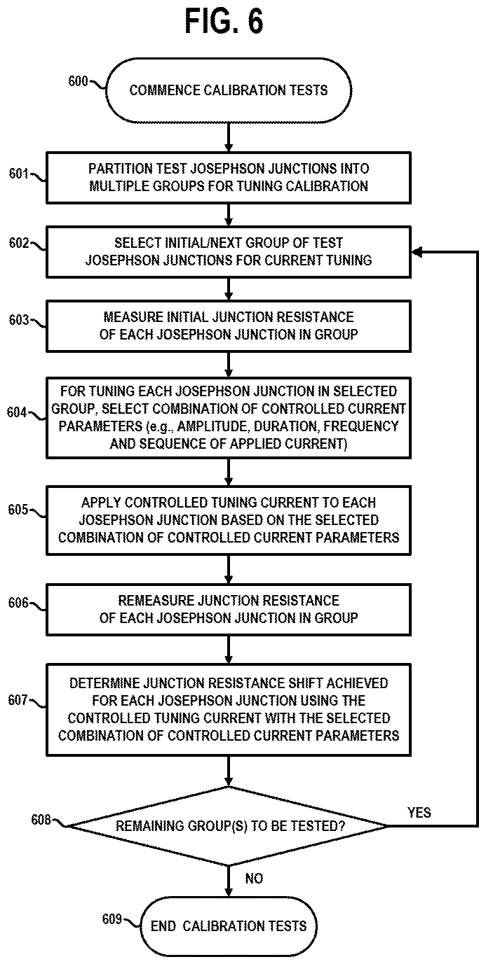

The calibration process proceeds by performing a series of trial tuning operations on a set of test Josephson junctions to obtain calibration data for tuning currents having different combinations of a plurality of different pulse amplitudes, different pulse duration, different pulse signal frequencies, etc. (block 501). For example, in some embodiments, to obtain calibration date for DC tuning current pulses, the calibration process can be performed by (i) selecting a set of discrete pulse amplitude settings within a range starting at 1.0 microampere (μA) to 100.0 μA in, e.g., multiples/increments of 5 μA, and (ii) selecting a set of discrete pulse durations (e.g., 5.0 s, 10.0 s, 15.0 s, . . . , 100.0 s) for each discrete pulse amplitude setting (e.g., a set of DC tuning current pulses with a same pulse amplitude of 10 μA but with different pulse durations, e.g., 5.0 s, 10.0 s, 15.0 s, . . . , 100.0 s. For each DC tuning current pulse with a given combination of pulse amplitude and pulse duration, tuning calibration operations are performed on a respective group of trial Josephson junctions (e.g., 3-10 Josephson junctions per group) to obtain a statistically significant amount of tuning calibration data. An exemplary calibration process for tuning a collection of test Josephson junctions to obtain tuning calibration data will be discussed in further detail below in conjunction with FIG. 6.

The calibration process analyzes the tuning calibration data to generate calibration tuning curves and associated calibration parameters (e.g., maximum tuning ranges, tuning rates, etc.) for the test Josephson junctions, for each combination of pulse amplitude and pulse duration of the tuning currents (block 502). As explained in further detail below, the tuning curves and associated calibration parameters for respective combinations of pulse amplitudes and pulse durations, provide information to enable a configuration of DC and/or AC tuning currents for precise tuning of the junction resistances of Josephson junctions to respective target junction resistances. The calibration data, calibration tuning curves and associated calibration parameters (e.g., maximum tuning ranges, tuning rates, etc.) are persistently stored (block 503) and the calibration process terminates (block 504). The persistently stored tuning curves and calibration parameters are subsequently utilized for calibrating current tuning operations that are to be performed on Josephson junctions to tune the respective junction resistances to respective target junction resistances, using current tuning processes discussed in further detail below.

FIG. 6 illustrates a flow diagram of a process for performing calibration tests on Josephson junctions to obtain tuning calibration data, according to an exemplary embodiment of the disclosure. In some embodiments, FIG. 6 illustrates an exemplary process for implementing block 501 (FIG. 5) to perform calibration tests on Josephson junction to obtain calibration data. Referring now to FIG. 6, a quantum chip is placed on the X-Y-Z stage 142 of the prober unit 140, and the control system 110 commences a calibration process to perform automated calibration tests (block 600). As noted above, the quantum chip comprises a collection of test Josephson junctions which are representative of actual Josephson junctions that are to be tuned using the calibration data obtained from the calibration process, wherein the quantum chip can be a sister chiplet or a quantum chip having a collection of test Josephson junctions that reside (e.g., in a kerf region) on the same quantum chip which has the Josephson junctions that are to be tuned.

The collection of test Josephson junctions are partitioned into multiple groups for tuning calibration (block 601). The number of groups will correspond to the number of different combinations of discrete pulse amplitudes and pulse durations for configuring DC tuning pulses, and/or different combinations of pulse frequencies, peak amplitudes, pulse envelopes, etc. for configuring AC tuning currents, which are selected for the calibration tests. For example, assuming that the calibration tests are performed using ten (10) discrete pulse amplitude (A) settings (e.g., A₁=1 μA, A₂=10 μA, A₃=20 μA, A₄=30 μA A₅=40 μA, A₆=50 μA, A₇=60 μA, A₈=70 μA, A₉=80 μA, and A₁₀=90 μA), and fourteen (14) different pulse durations (dt) in seconds (s) (e.g., 5 s, 10 s, 15 s, 20 s, 25 s, 30 s, 35 s, 40 s, 45 s, 50 s, 55 s, 60 s, 65 s, and 70 s) for each discrete pulse amplitude setting, the collection of test Josephson junctions would be partitioned into (10×14) 140 test groups, wherein each test group would have a desired number of test Josephson junctions (e.g., 3, 4, 5, 6, 7 etc.) to obtain a given amount of calibration data with statistical significance.

The calibration process selects an initial group of test Josephson junctions for current tuning to obtain calibration data (block 602) and proceeds to resistance measurements to measure an initial junction resistance (Rᵢₙᵢₜᵢₐₗ) of each test Josephson junction of the given group (block 603). For example, in some embodiments, the resistance measurements are performed using a 4-wire (Kelvin) resistance measurement process, as discussed above. Then, for tuning each Josephson junction in the selected group, the calibration process selects a given combination of controlled tuning current parameters (e.g., pulse amplitude, pulse duration, frequency, sequence of applied current, etc.) to configure a tuning current pulse to be applied to each test Josephson junction in the selected group (block 604). For example, for a given calibration iteration, the calibration process can select a pulse amplitude setting A₁=1 μA and a pulse duration (dt) setting of 5 s, and apply a DC tuning pulse with A₁=1 μA and dt=5 s to each test Josephson junction in the selected group, wherein for each subsequent calibration iteration on remaining groups test Josephson junction, the calibration process can select a different combination of a pulse amplitude and pulse duration.

The calibration process proceeds to generate and apply a controlled tuning current (e.g., DC pulse) based on the selected combination of tuning current parameters (e.g., pulse amplitude and pulse duration) to each test Josephson junction of the given group (block 605). Next, junction resistance measurements are performed to remeasure the junction resistances of each test Josephson junction of the given group to determine the current junction resistance R_{current} of each test Josephson junctions following the current tuning operations (block 606). The resistance measurement data (e.g., Rᵢₙᵢₜᵢₐₗ and R_{current}) for each test Josephson junctions of the given group is analyzed to determine an amount of junction resistance shift achieved for each Josephson junction in the given group using the controlled tuning current (e.g., DC pulse) based on the selected combination of controlled tuning current parameters (e.g., pulse amplitude, pulse duration, etc.) (block 607). For example, as noted above, in some embodiments, the amount of junction resistance shift ΔR for a given test Josephson junction is determined as: ΔR=R_{current}−Rᵢₙᵢₜᵢₐₗ (and with a “resistance shift percentage” determined as:

$$Δ R \% = \frac{Δ R}{{R}_{initial}} \times 100 \% ) .$$

The resistance measurement data (e.g., Rᵢₙᵢₜᵢₐₗ, R_{current} and computed ΔR) for each test Josephson junction at the given combination of pulse amplitude and pulse duration is stored (block 607) for subsequent access and analysis. In some embodiments, the calibration process computes an average of the measured junction resistance shift percentages ΔR % for all Josephson junctions in the group, wherein the average junction resistance shift percentage ΔR_{avg}% is stored for subsequent calibration analysis.

Next, the calibration process determines whether there are one or more remaining groups of test Josephson junctions to perform calibration tests using tuning currents (e.g., DC pulses) with other combinations of pulse amplitude and pulse duration settings (block 608). If there are one or more are one or more remaining groups of test Josephson junctions to be tested (affirmative determination in block 608), the calibration process selects a next group of test Josephson junctions (return to block 602) and repeats the calibration test (repeat block 603, 604, 605, 606, and 607) on the next selected group of test Josephson junctions using a tuning current (e.g., DC pulse) configured with a next selected combination of pulse amplitude and pulse duration settings. On the other hand, if there are no remaining groups of test Josephson junctions to be tested (negative determination in block 608), the calibration tests are ended (block 609).

In some embodiments, at the completion of the calibration tests of FIG. 6, the calibration process comprises a collection of computed ΔR data or ΔR % data, which is utilized to compute calibration tuning parameters/metrics, e.g., (i) compute tuning curves that represent tuning rates of the test Josephson junctions for the each of the different pulse amplitudes as a function of the different pulse durations and (ii) determine maximum tuning ranges for each of the different pulse amplitudes before junction breakdown (e.g., regions 306 and 316 in FIGS. 3B and 3D).

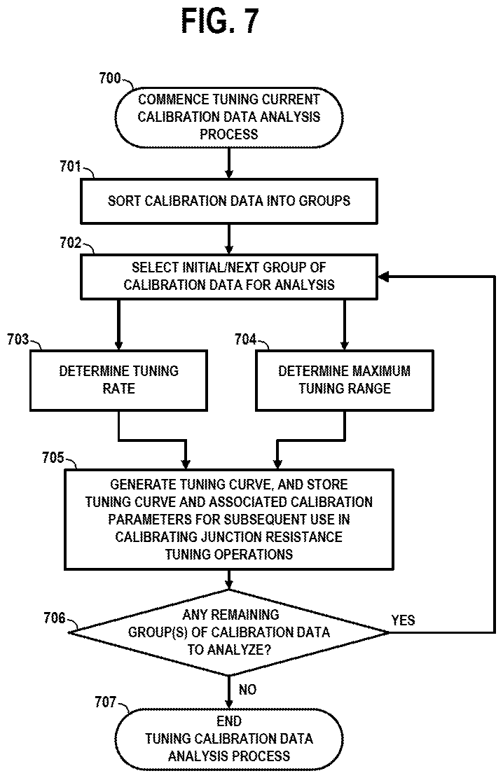

FIG. 7 illustrates a flow diagram of a process for analyzing tuning calibration data to determine tuning curves and associated calibration parameters for tuning junction resistances of Josephson junctions, according to an exemplary embodiment of the disclosure. In some embodiments, FIG. 7 illustrates an exemplary process for implementing block 502 (FIG. 5) to compute tuning curves and calibration parameters for each pulse amplitude setting of, e.g., DC tuning current pulses. In some embodiments, after performing the calibration tests (FIG. 6), the control system 110 commences a tuning calibration data analysis process (block 700) to compute tuning curves and calibration parameters for, e.g., each of the DC pulse amplitude settings as a function of different pulse durations.

For example, as an initial step, the calibration process accesses and sorts the calibration data acquired for each test group of Josephson junctions into groups of calibration data (block 701). More specifically, in some embodiments, for each pulse amplitude setting of the DC current tuning, the calibration process aggregates the resistance shift data resulting from the groups of test Josephson junctions that were tuned using the same pulse amplitude setting, at each of the different pulse durations. In other words, this sorting process results in multiple groups of calibration data for analysis, where each group of calibration data comprises an aggregation of the resistance shift data of test Josephson junctions obtained from performing current tuning calibrations operations on the test Josephson junctions for the various pulse duration settings at the same pulse amplitude setting. The sorting of the calibration data into groups of calibration data allows the calibration data to be fitted to tuning curves for each discrete pulse amplitude setting.

The calibration process selects an initial (or next) group of calibration data for analysis (block 702). For example, the initial group of calibration data can include the resistance shift data (ΔR data) associated with groups of test Josephson junctions that were tuned using a DC current pulse with the same pulse amplitude setting A₁=1 μA, but at the different pulse duration settings (dt) (e.g., 5 s, 10 s, 15 s, 20 s, 25 s, 30 s, 35 s, 40 s, 45 s, 50 s, 55 s, 60 s, 65 s, and 70 s). The group of calibration data is analyzed to determine a tuning rate coefficient for the positive tuning region (e.g., positive tuning regions 304 and 314, FIGS. 3A and 3C) for the given pulse amplitude duration (block 703) and to determine a maximum tuning range for the positive tuning region for the given pulse amplitude duration (block 704). In some embodiments, the tuning rate coefficients and maximum tuning ranges are determined based average junction resistance shift percentage data (ΔR_{avg}%) that is computed using the measured junction resistance shift percentage data (ΔR %) of the test Josephson junctions, for each of the different pulse durations at the given pulse amplitude setting.

For example, assume that the given group of calibration data comprises the ΔR % data for the test Josephson junctions that were tuned with a DC current pulse having the same pulse amplitude setting A₁=1 μA. The measured ΔR % data for each test Josephson junction that was tuned using a DC pulse with a pulse duration of, e.g., 5 s (at the given pulse amplitude setting A₁=1 μA) is utilized to determine the ΔR_{avg}% for the given pulse duration of 5 s at the given pulse amplitude setting A₁=1 μA. Similarly, the measured ΔR % data for each test Josephson junction that was tuned using a DC pulse with a pulse duration of 10 s (at the given pulse amplitude setting A₁=1 μA) is utilized to determine the ΔR_{avg}% for the given pulse duration of 10 s at the given pulse amplitude setting A₁=1 μA. The same ΔR_{avg}% is computed for each pulse duration setting (e.g., (e.g., 15 s, 20 s, 25 s, etc.) at the given pulse amplitude setting A₁=1 μA, and the same computations are repeated using the corresponding ΔR % data for each of the groups of test Josephson junctions that were tuned using DC pulses with different pulse amplitude settings for the different pulse duration settings.

In some embodiments, the ΔR_{avg}% parameters that are determined for the different pulse duration settings for a given pulse amplitude setting are utilized to compute a tuning curve for the given pulse amplitude setting (block 705). For example, in some embodiments, the tuning curve for a given pulse amplitude setting is determined using a curve fitting process to fit the ΔR_{avg}% data points of the different pulse duration settings for the given pulse amplitude setting to a curve using a polynomial curve fitting process (e.g., a second order (or higher order) polynomial curve fitting process). In other embodiments, the tuning curve for a given pulse amplitude setting is determined using a nonlinear regression process to fit the ΔR_{avg}% data points for the given pulse amplitude setting to a curve using, for example, a logarithmic, or inverse exponential curve. Moreover, in some embodiments, the maximum tuning range for the given pulse amplitude setting can be determined using an interpolation function (polynomial, logarithmic, or the like) where the maximum value(s) may be extracted from the extrema(s) of the tuning curve that is computed using a linear or nonlinear regression curve fitting process.

In some embodiments, the calibration process utilizes the ΔR_{avg}% data points of the different pulse duration settings for the given pulse amplitude setting to generate a tuning curve for the given pulse amplitude setting and persistently stores the tuning curve and associated calibration parameters (e.g., tuning rate coefficients and maximum tuning ranges) that are derived from the ΔR_{avg}% data, for subsequent use in calibrating tuning operations (block 705). For example, in some embodiments, the tuning curve and associated calibration parameters are stored in a database of calibration data (e.g., the database of tuning calibration data 116, FIG. 1).

If there are any remaining groups of calibration data to be analyzed (affirmative determination in block 706), the calibration process selects the next group of calibration data for analysis (return to block 702), and the process steps of blocks 703, 704, and 705 are repeated for the next selected group of calibration data. The tuning calibration data analysis process terminates (block 707) after all groups of calibration data have been analyzed. At the completion of the tuning calibration data analysis process, the tuning calibration database can have computed tuning curves associated calibration parameters for configurating tuning currents (e.g., DC current pulses, AC current signals) for different pulse amplitude settings.

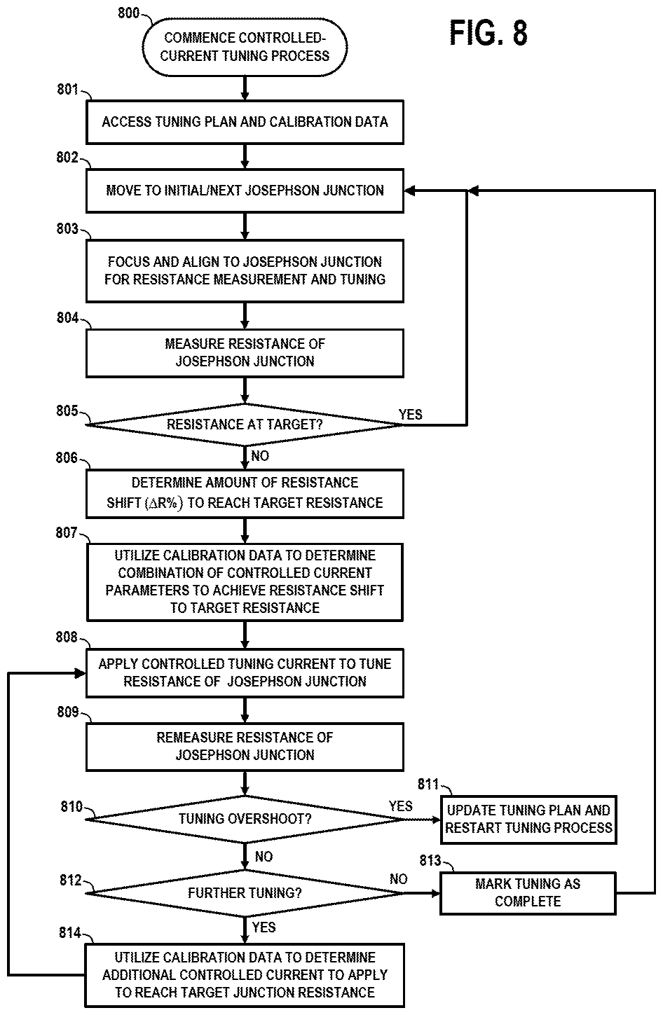

FIG. 8 illustrates a flow diagram of a method for tuning junction resistances of Josephson junctions, according to another exemplary embodiment of the disclosure. In some embodiments, FIG. 8 illustrates an automated controlled-current tuning process, which can be performed using the system 100 of FIG. 1, to tune Josephson junctions to respective R_{target} values and thereby tune superconducting qubits in a qubit lattice on a quantum chip to respective target transition frequencies as specified by a frequency tuning plan. The controlled-current tuning process of FIG. 8 is similar to the controlled-current tuning process of FIG. 4, except that the controlled-current tuning process of FIG. 8 is configured to utilized tuning calibration data to accurately determine and configured tuning currents (e.g., DC or AC tuning currents) and thereby more precisely control the tuning of junction resistance of Josephson junctions.

Referring to FIG. 8, a quantum chip is placed on the X-Y-Z stage 142 of the prober unit 140, and the control system 110 commences an automated controlled-current tuning process (block 800). The quantum chip comprises a plurality of superconducting qubits arranged in a given qubit lattice. The controlled-current tuning process accesses a frequency tuning plan generated for the given qubit lattice, and tuning calibration data associated with the Josephson junctions of the superconducting qubits (block 801). In some embodiments, the frequency tuning plan specifies respective R_{target} values for the Josephson junctions, as well as calibration parameters for determining, e.g., suitable pulse amplitude and pulse duration settings, etc., for generating tuning currents (e.g., DC current pulses) for tuning the Josephson junctions of the superconducting qubits.

The automated controlled-current tuning process selects an initial Josephson junction of an initial superconducting qubit in the lattice and moves to the selected Josephson junction (block 802) using techniques such as discussed above. The controlled-current tuning process initiates control operations to cause the microscope unit and the probe unit to perform a focus and alignment process to ensure a proper focus to the focal plane and proper alignment of the target Josephson junction within the FOV of the microscope unit 130 for the purpose of contacting the electrical probes to the contact pads for the Josephson junction to perform junction resistance measurement and tuning operations (block 803).

Next, the controlled-current tuning process proceeds to measure the initial junction resistance Rᵢₙᵢₜᵢₐₗ of the target Josephson junction (block 804) using techniques as discussed above. For example, in some embodiments, a junction resistance measurement is performed using a 4-wire (Kelvin) probe resistance measurement operation, such as describe above in conjunction with FIG. 2A, whereby a constant current (DC current pulse) is passed through the Josephson junction, and a resulting voltage across the Josephson junction is measured, and the junction resistance is determined based on the magnitude of the constant current and the measured voltage. In some or other embodiments, the junction resistance is determined using a 4-wire (Kelvin) probe resistance measurement operation, whereby a constant voltage is sourced across the Josephson junction, and the resulting current is measured, and the junction resistance is determined based on the magnitude of the constant voltage and the measured current. Moreover, in some embodiments, contact resistance and contact stability checks are initially performed, prior to performing the junction resistance measurement, to ensure that the contact resistance is below a given threshold, and to ensure that the contact between the electrical probe and the contact pads of the Josephson junction and stable and not intermittent.

Next, a determination is made as to whether the initial junction resistance Rᵢₙᵢₜᵢₐₗ of the Josephson junction is at or near the specified target resistance (block 805). For example, as noted above, in some embodiments, the junction resistance of the given Josephson junction will be deemed to be at or near the target junction resistance R_{target} if the currently measured junction resistance is within some specified threshold percentage (e.g., ±0.3%) of the target junction resistance R_{target}. When the given Josephson junction has an initial junction resistance Rᵢₙᵢₜᵢₐₗ which deemed to be at or near its target junction resistance R_{target}, it is assumed that the corresponding superconducting qubit is properly tuned and is within a corresponding bound of precision to its respective target transition frequency.

In this regard, if the initial junction resistance Rᵢₙᵢₜᵢₐₗ of the Josephson junction is determined to be at or near the specified target resistance (affirmative determination in block 805), the controlled-current tuning process selects a next Josephson junction of a next superconducting qubit to be tuned (return to block 802). On the other hand, if the initial junction resistance Rᵢₙᵢₜᵢₐₗ of the Josephson junction is determined to not be at or near the specified target resistance (negative determination in block 805), the controlled-current tuning process will proceed to determine an amount of resistance shift, ΔR_{target}=R_{target}−Rᵢₙᵢₜᵢₐₗ, which is needed to reach the target junction resistance R_{target} (block 806). In some embodiments, the controlled-current tuning process determines

$$Δ {R}_{target} \% = \frac{Δ {R}_{target}}{{R}_{initial}} \times 100 \% .$$

Next, the controlled-current tuning process utilizes the determined amount of resistance shift (e.g., ΔR_{target} or ΔR_{target}%) to determine, from the calibration data, a suitable combination of controlled tuning current parameters (e.g., pulse amplitude, pulse duration, etc.) which can be used to configure a tuning current (e.g., DC pulse) to apply to the given Josephson junction to achieve a sufficient shift of the junction resistance of the given Josephson junction to tune the given Josephson junction to the target junction resistance R_{target} (block 807). The controlled-current tuning process then configures and applies the controlled tuning current to the given Josephson junction to tune the junction resistance, e.g., shift the junction resistance towards the target junction resistance of the given Josephson junction (block 808).

After applying the initial tuning current, the controlled-current tuning process proceeds to remeasure the junction resistance of the given Josephson junction (block 809). This process can be performed as discussed above, by applying a low magnitude DC current to the given Josephson junction and measuring a resulting voltage drop across the Josephson junction to determine the junction resistance. In other embodiments, as noted above, the junction resistance measurement operation can be performed concurrently with the tuning operation, whereby the tuning process can continuously measure voltage drop across the Josephson junction which is generated as a result of the tuning current, and then continuously determine/track the increase in the junction resistance during the tuning operation. This allows the controlled-current tuning process to terminate the flow of the tuning current when the measured junction resistance is determined to have reached target junction resistance.

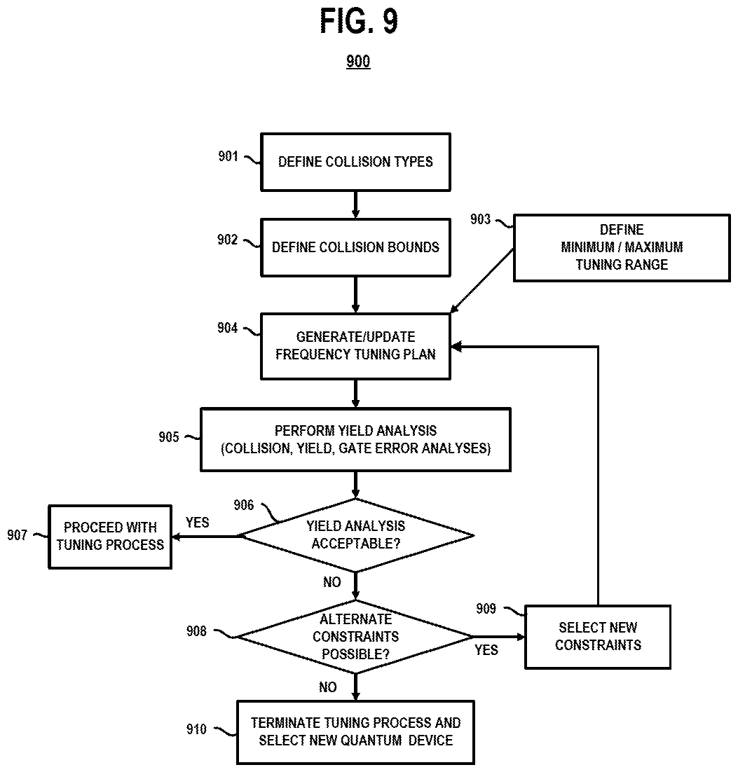

In all instances, the controlled-current tuning process will determine whether or not the junction resistance of the given Josephson junction has exceeded the target junction resistance resulting in an undesired tuning overshoot (block 810). If the controlled-current tuning process determines that a tuning overshoot has resulted for the given Josephson junction (affirmative determination in block 810), the controlled-current tuning process can be paused, to allow a new or updated frequency tuning plan to be generated which takes into account the tuning overshoot of the given Josephson junction (block 811), which case the controlled-current tuning process can be restarted using the new or updated frequency tuning plan. An exemplary process for generating a new or updated frequency tuning plan will be discussed in further detail below in conjunction with FIG. 9.

On the other hand, if the controlled-current tuning process determines that a tuning overshoot has not resulted for the given Josephson junction (negative determination in block 810), the controlled-current tuning process will determine if further resistance tuning is needed to reach the target junction resistance of the given Josephson junction (block 812). For example, in some embodiments, as noted above, a determination is made as to whether the remeasured junction resistance R_{current} is at or near the target junction resistance R_{target} within some specified threshold percentage (e.g., ±0.3%) of the target junction resistance R_{target}. If the controlled-current tuning process determines that no further resistance tuning is needed to reach the target junction resistance of the given Josephson junction (negative determination in block 812), the tuning for the given Josephson junction will be marked complete (block 813), and the controlled-current tuning process selects a next Josephson junction of a next superconducting qubit to be tuned (return to block 802) and repeats the controlled-current tuning process for the next Josephson junction.

On the other hand, if the controlled-current tuning process determines that further resistance tuning is needed to reach the target junction resistance of the given Josephson junction (affirmative determination in block 812), the controlled-current tuning process will utilize the calibration data to determine an additional amount of the controlled tuning current (e.g., same tuning current parameters, with adjusted duration) to apply to the Josephson junction, which is sufficient to cause a further shift in the junction resistance of the given Josephson junction to the target junction resistance (block 814). The controlled-current tuning process will then proceed to apply the additional tuning current to the Josephson junction to shift the junction resistance to the target junction resistance (return to block 808), and the process flow (blocks 809-814) is repeated for the given Josephson junction.

While FIG. 8 is discussed in the context of utilizing calibration data to determine DC tuning pulses to tune the junction resistances of Josephson junctions, it is to be noted that the same or similar process flow can be implemented in the context of utilizing calibration data to determine tuning parameters for configuring AC tuning pulses (e.g., pulse frequency, peak amplitudes, and/or pulse envelope shape, etc.) to tune the junction resistances of Josephson junction. Moreover, while exemplary junction resistance measurement and tuning operations (e.g., FIGS. 2, 4, and 8) can be implemented at room temperature, as noted above, the junction resistance measurement and tuning operations can be performed at low temperatures using, e.g., the thermoelectric element 143 of the X-Y-Z stage 142 (FIG. 1). For example, low temperature junction resistance measurements (e.g., in range of about −20° C. to about −60° C. enables more precise resistance measurements by, e.g., performing low noise electrical measurements by suppressing noise that is intrinsic to the Josephson junction itself, as well as reducing the contribution of substrate conductivity on the junction resistance measurement. Moreover, in some embodiments, AC junction resistance measurements can be performed (e.g., at a frequency of about 1.0 kHz or greater), wherein high-frequency resistance measurements are configured to mitigate 1/f noise, and thereby increase the precision of the junction resistance measurements.

FIG. 9 illustrates a flow diagram of a method 900 for generating and updating a frequency tuning plan of a quantum bit array, according to an exemplary embodiment of the disclosure. In some embodiments, the method 900 of FIG. 9 can be utilized to generate an initial frequency tuning plan for a given quantum bit array prior to commencing a tuning process (e.g., a controlled-current tuning process, or a hybrid tuning process, as discussed below). Further, as noted above, the process of FIG. 9 can be utilized to modify/update the frequency tuning plan (e.g., implement block 811 in FIG. 8) during a tuning process, as needed, based on the progression of the tuning process to ensure that a yield rate remains acceptable. As noted above, a frequency tuning plan is generated to assist in tuning the transition frequencies of superconducting qubits in a given qubit lattice to avoid frequency collisions in the qubit lattice when performing gate operations (e.g., single gate operations, multi-gate operations (e.g., two-qubit gate entanglement operations, etc.) on a quantum chip (e.g., quantum processor).

Referring to FIG. 9, the method 900 involves defining/determining a plurality of key constraints for a given frequency tuning plan including defining various types of frequency collisions that may occur based on a given qubit lattice architecture (block 901), defining bounds of such collisions (block 902), and defining tuning ranges, e.g., minimum and maximum tuning ranges (block 903). In some embodiments, the tuning ranges are derived by analyzing the tuning calibration data obtained from calibration tests performed on the groups of test Josephson junctions using controlled calibration current, such as discussed above.

The process proceeds to generate or update the frequency tuning plan (block 904) based on, e.g., the defined collision types, the frequency collision bounds for each collision type, the maximum/minimum tuning ranges, etc. In some embodiments, the tuning plan generation process determines respective target junction resistances (R_{target}) for the Josephson junctions of the superconducting qubits to achieve frequency collision avoidance. More specifically, in some embodiments, the tuning plan generation process determines the respective target junction resistances (R_{target}) for the Josephson junctions of the qubits based on initial measured junction resistances (Rᵢₙᵢₜᵢₐₗ) of the Josephson junctions and the tuning range calibration data associated with the Josephson junctions of the qubits. The target junction resistances (R_{target}) of the respective Josephson junctions of the qubits are utilized to predict the target transition frequencies of the respective qubits.

After generating or updating the frequency tuning plan, the process performs a yield estimate process to analyze the frequency tuning plan (block 905). In some embodiments, the yield estimate process is performed using Monte Carlo simulations to statistically determine how many frequency collisions are expected based on the given frequency tuning plan, and performing other analytical processes for gamma computations, gate error modeling, etc. The yield analysis is performed to predict and quantify collisions and zero-collision probability and gate fidelity comparing against pre-defined acceptance thresholds. In particular, in some embodiments, the yield analysis comprises performing collision analysis for nearest-neighbor and next nearest-neighbor degeneracies. In addition, a statistical analysis (e.g., Monte Carlo) is performed to identify an expected number of collisions given a frequency prediction imprecision, or set of frequency prediction imprecisions. In addition, a collision yield is computed to obtain a zero-collision probability, and a gate error analysis is performed to estimate gate fidelities (error yield).

If the results of the yield analysis are acceptable (affirmative determination in block 906), the updated frequency tuning plan is deemed to be acceptable and the tuning process proceeds based on the updated frequency tuning (block 907). On the other hand, if the results of the yield analysis are deemed to be unacceptable (negative determination in block 906), the frequency tuning plan is deemed to be unacceptable given the existing tuning state of the Josephson junctions. As a result, the process proceeds to determine if alternate constraints are possible for revising the tuning plan to achieve a favorable yield analysis (block 908). For example, in some embodiments, alternate constraints include, e.g., increasing the tuning range, changing frequency collision weights or collision bounds, etc.

If alternate constraints are possible (affirmative determination in block 909), the method 900 proceeds to select new constraints (block 909), generate a new or updated frequency tuning plan based on the new constraints (return to block 1410), and perform another yield analysis (block 905) based on the new or updated frequency tuning plan and the existing tuning state of the Josephson junctions. On the other hand, if there exists a given circumstance in which no alternate constraints are possible for generating new tuning plan (negative determination in block 908), the tuning process terminates for the given quantum device, and a new quantum device is selected for tuning (block 910).

In other embodiments, as noted above, a hybrid tuning process is implemented to tune the junction resistances of superconducting tunnel junction devices (e.g., Josephson junctions) using a combination of laser tuning and controlled-current tuning to tune the junction resistances of, e.g., Josephson junctions of qubits. In this regard, exemplary calibration techniques are implemented to obtain hybrid tuning calibration data by performing joint trial laser tuning and controlled-current tuning calibration operations on representative hardware comprising Josephson junction (e.g., qubits with Josephson junctions), and utilize the tuning calibration data to determine various tuning metrics including, e.g., tuning rates and maximum tuning ranges for various combinations of laser annealing parameters (e.g., laser power, laser anneal time, optional laser beam illumination pattern), and controlled current parameters (e.g., pulse amplitude, pulse duration, pulse frequency, sequence of applied current, etc.) and utilize the tuning metrics to configure a hybrid tuning process for laser tuning and controlled-current tuning of Josephson junction on a quantum chip.

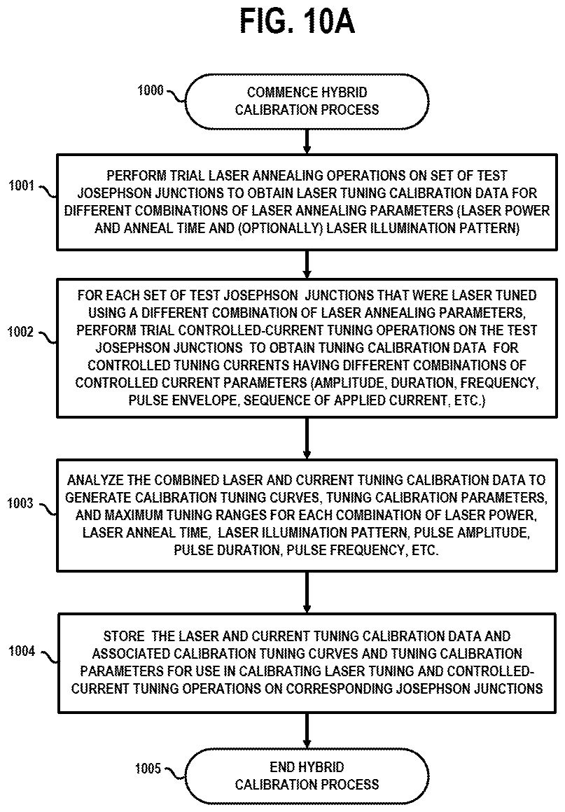

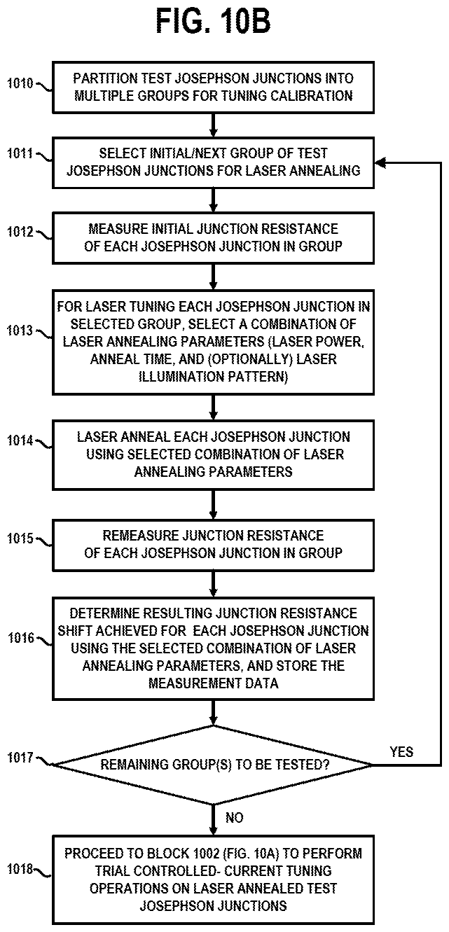

For example, FIGS. 10A and 10B are flow diagrams which illustrate a hybrid calibration process to obtain tuning calibration data for using in configuring a hybrid tuning process for laser tuning and controlled-current tuning of Josephson junctions, according to an exemplary embodiment of the disclosure. Referring to FIG. 10A, a quantum chip is placed on the X-Y-Z stage 142 of the prober unit 140, and the control system 110 commences a hybrid calibration process (block 1000) to perform automated calibration tests. As noted above, the quantum chip comprises a collection of test Josephson junctions which are representative of actual Josephson junctions that are to be tuned using the hybrid calibration data obtained from the hybrid calibration process. The quantum chip can be a sister chiplet or a quantum chip having a collection of test Josephson junctions that reside (e.g., in a kerf region) on the same quantum chip which has the Josephson junctions that are to be tuned. The collection of test Josephson junctions are partitioned into multiple groups for tuning calibration. For the hybrid calibration process, in some embodiments, the number of test groups will correspond to a total number of (i) different combinations of laser annealing parameters (e.g., laser power, laser anneal time, laser beam illumination pattern) and (ii) different combinations of controlled current parameters (pulse amplitude, pulse duration, pulse frequencies, pulse envelopes, sequence of applied current, etc.), which are selected for the hybrid calibration tests.

An initial phase of the hybrid calibration process comprises performing trial laser anneal operations on set of test Josephson junctions to obtain laser tuning calibration data for different combinations of laser annealing parameters (e.g., laser power, laser anneal time and (optionally) laser illumination pattern) (block 1001). An exemplary process for performing trial laser anneal operations will be discussed in further detail below in conjunction with FIG. 10B.

In a next phase, for each set of test Josephson Junctions that were laser tuned using a different combination of laser annealing parameters, the hybrid calibration process proceeds to perform trial controlled-current tuning operations on the test Josephson junctions to obtain tuning calibration data for controlled tuning currents having different combinations of controlled current parameters (e.g., amplitude, duration, frequency, pulse envelope, sequence of applied current, etc.) (block 1002). In some embodiments, the trial controlled-current tuning process (of block 1002) is performed using the same or similar process flow as discussed above, in conjunction with FIG. 6. However, for the hybrid calibration process, each group of test Josephson junctions that were laser tuned (for the different combinations of laser annealing parameters) is further partitioned into additional groups (or subgroups) of test Josephson junctions for performing the controlled-current tuning calibration operations (of block 1002). The number of subgroups of test Josephson junctions for each group of laser-annealed test Josephson junctions will correspond to the number of different combinations of controlled current parameters (e.g., amplitude, duration, frequency, pulse envelope, sequence of applied current, etc.) that are specified for controlled-current calibration tests. At the completion of the controlled-current calibration test, each group of test Josephson junctions will have an associated set of hybrid calibration data which corresponds to a unique combination of laser annealing parameters and controlled current parameters.

The combined (hybrid) laser and current tuning calibration data is then analyzed to generate calibration tuning curves, and determine tuning calibration parameters, and maximum tuning ranges for each unique combination of laser annealing parameters and controlled current parameters (e.g., laser power, laser anneal time, laser beam illumination pattern, pulse amplitude, pulse duration, pulse frequency, etc.) (block 1003). In some embodiments, the analysis is performed using the same or similar process flow as discussed above in conjunction with FIG. 7. However, for the hybrid calibration data analysis, the tuning calibration data provides further information regarding the tuning characteristics of test Josephson junctions with regard to resistance shifts achieved with laser tuning with various laser annealing parameters. The combined (hybrid) laser and current tuning calibration data, and associated calibration tuning curves and tuning calibration parameters are then persistently stored in the database of tuning calibration data 116 (FIG. 1) for use in calibrating laser tuning and controlled-current tuning operations on corresponding Josephson junctions (block 1004), and the hybrid calibration process ends (block 1005).

FIG. 10B illustrates a flow diagram of a process for performing calibration tests on Josephson junctions to obtain laser tuning calibration data, according to an exemplary embodiment of the disclosure. In some embodiments, FIG. 10B illustrates an exemplary process for implementing block 1001 (FIG. 10A) to perform trial laser annealing operations on set of test Josephson junctions to obtain laser tuning calibration data for different combinations of laser annealing parameters. A quantum chip is placed on the X-Y-Z stage 142 of the prober unit 140, and the control system 110 commences an initial phase of the hybrid calibration process to obtain laser tuning calibration data. As noted above, the quantum chip comprises a collection of test Josephson junctions which are representative of actual Josephson junctions that are to be tuned using the hybrid calibration data obtained from the hybrid calibration process, wherein the quantum chip can be a sister chiplet or a quantum chip having a collection of test Josephson junctions that reside (e.g., in a kerf region, or dedicated region of test devices) on the same quantum chip which has the Josephson junctions that are to be tuned. In this regard, the test Josephson junctions on the test chip (e.g., sister chiplet), or on the same chip, are assumed to have the same, or substantially the same, or similar laser tuning characteristics as the Josephson junctions on the actual chip which are to be tuned by laser annealing operations that are configured using the calibration data obtained from the laser tuning calibration operations performed on the test Josephson junctions on the test chip.

The collection of test Josephson junctions are partitioned into multiple groups for tuning calibration (block 1010). For the hybrid calibration process, in some embodiments, the number of test groups will initially correspond to the number of different combinations of laser annealing parameters (e.g., laser power, laser anneal time, laser beam illumination pattern). The calibration process proceeds by performing a series of trial laser anneal operations on the set of test Josephson junctions to obtain calibration data for different combinations of laser annealing parameters such as laser power, laser anneal time, and (optionally) laser beam illumination patterns.

For example, in some embodiments, the calibration process is performed by selecting a plurality of discrete laser power settings from low power to high power, e.g., 1.20 watts (W), 1.60 W, 1.80 W, and 2.0 W, and a plurality of anneal times for each laser power setting, e.g., a set of anneal times 0.5 s, 1.0 s, 2.0 s, 5.0 s, 10.0 s, 20.0 s, and 100 s for each of the discrete laser power settings (e.g., 1.60 watts at anneal times of 0.5 s, 1.0 s, 2.0 s, 5.0 s, 10.0 s, 20.0 s, and 100 s, etc.). Further, in some embodiments, each power/anneal time combination for the calibration process is performed using two or more different laser beam illumination patterns. For each combination of laser power, anneal time, and (optional) laser beam illumination pattern, laser annealing operations are performed on a respective group of trial Josephson junctions to obtain a statistically significant amount of tuning calibration data.

For the hybrid calibration process, each group of test Josephson junctions will have a sufficient number of test Josephson junctions (e.g., 25 to 100 test Josephson junctions) that are laser annealed using a respective unique combination of laser annealing parameters each group of laser annealed test Josephson junctions can be further partitioned into groups (subgroups) of test Josephson junctions where the number subgroups in each group of laser anneal test Josephson junctions will correspond to the number of unique combinations of controlled tuning current parameters.

The calibration process selects an initial group of test Josephson junctions for laser annealing to obtain calibration data (block 1011) and proceeds to perform in-situ resistance measurements to measure the initial junction resistance (Rᵢₙᵢₜᵢₐₗ) of each test Josephson junction of the given group (block 1012). For example, in some embodiments, the in-situ resistance measurements are performed using a 4-wire (Kelvin) resistance measurement process, as discussed herein. For laser tuning each test Josephson junction in the selected group, the calibration process selects a given unique combination laser annealing parameters (e.g., unique combination of laser power and anneal time and (optionally) laser beam illumination pattern) to laser anneal each test Josephson junction in the given group (block 1013). For example, for the given calibration iteration, the calibration process can select the low laser power setting (e.g., 1.2 W) and an anneal time t_{A1}=0.5 s as the initial selection (and optional laser beam illumination pattern (e.g., quad-spot pattern, see FIG. 13A)), wherein for each subsequent calibration iteration on remaining groups test Josephson junction, the calibration process can select a different combination of laser power setting and anneal time (and optional illumination pattern).

The calibration process proceeds to laser anneal each test Josephson junction of the given group, in succession, using the selected combination of laser annealing parameters (block 1014). Next, in-situ resistance measurements are performed to remeasure the junction resistances of each test Josephson junction of the given group to determine the current junction resistance R_{current} of each test Josephson junctions following the laser anneal operations (block 1015). In some embodiments, a given time delay is imposed after the laser annealing operations before remeasuring the junction resistances to allow the test Josephson junctions to settle to a stable resistance state following the completion of a laser annealing of the test Josephson junctions. The time delay can be on the order of, e.g., a minute (or minutes), or an hour (or hours), etc., or any time as needed to allow the test Josephson junctions to settle to a stable resistance state following the completion of a laser annealing.

Following the resistance remeasurements (block 1015), the resistance measurement data (e.g., Rᵢₙᵢₜᵢₐₗ and R_{current}) for each test Josephson junctions of the given group is used to determine an amount of junction resistance shift that occurs as a result of the laser annealing the test Josephson junctions at the given combination of laser power and anneal time (block 1016). For example, as noted above, in some embodiments, the amount of junction resistance shift ΔR for a given test Josephson junction is determined as: ΔR=R_{current}−Rᵢₙᵢₜᵢₐₗ (and with a “resistance shift percentage” determined as:

$$Δ R \% = \frac{Δ R}{{R}_{initial}} \times 100 ) .$$

The resistance measurement data (e.g., Rᵢₙᵢₜᵢₐₗ, R_{current} and computed ΔR) for each test Josephson junction at the given combination of laser annealing parameters (e.g., laser power and anneal time) is stored for subsequent access and analysis.

Next, the calibration process determines whether there are one or more remaining groups of test Josephson junctions to perform laser annealing calibration tests using other unique combinations of laser annealing parameters (block 1017). If there are one or more are one or more remaining groups of test Josephson junctions to be tested (affirmative determination in block 1017), the calibration process selects a next group of test Josephson junctions (return to block 1011) and repeats the laser annealing calibration test (repeat blocks 1012, 1013, 1014, 1015, and 1016) on the next selected group of test Josephson junctions using a next selected combination of laser annealing parameters.

At the completion of the laser annealing calibration tests of FIG. 10B, the hybrid calibration process proceeds to block 1002 of FIG. 10A to perform the trial controlled-current tuning operations on the laser anneal test Josephson junctions. At the completion of the controlled-current calibration tests, the hybrid calibration process will have a collection of computed ΔR data or ΔR % data, which is utilized to compute calibration tuning metrics for calibrating laser tuning and controlled-current tuning operations. Such calibration tuning metrics include, e.g., tuning curves that represent tuning rates of the test Josephson junctions for the different combinations of laser annealing parameters and controlled tuning current parameters, as well as maximum tuning ranges (e.g., maximum ΔR %), and other metrics as discussed herein, which are representative of the laser tuning characteristics and controlled-current tuning characteristics of the test Josephson junctions.

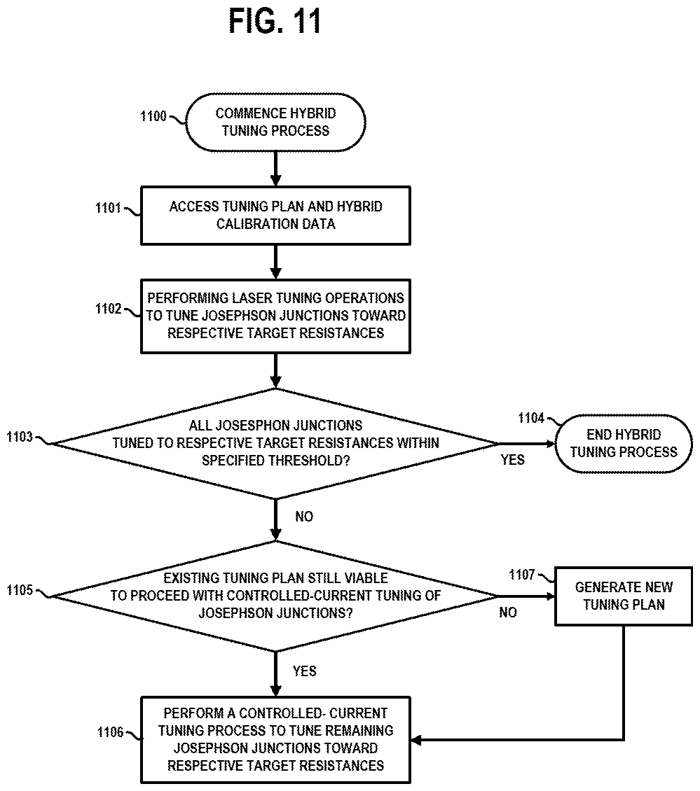

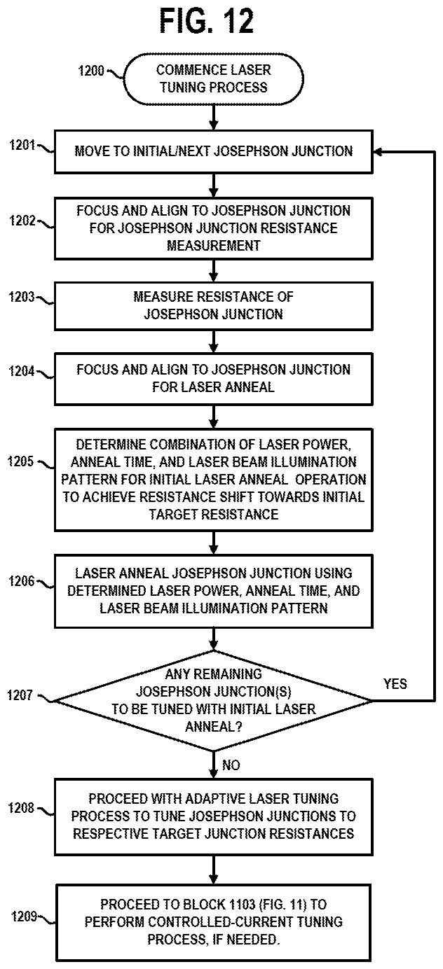

The exemplary tuning curves and associated tuning calibration parameters are utilized to calibrate laser tuning operations and controlled-current tuning operations of a hybrid tuning process for shifting the resistances of Josephson junctions to respective target junction resistances. For example, FIG. 11 illustrates a flow diagram of a method for performing a hybrid tuning process to tune junction resistances of Josephson junctions, according to an exemplary embodiment of the disclosure. In some embodiments, FIG. 11 illustrates an automated hybrid tuning process, which can be performed using the system 100 of FIG. 1, to tune Josephson junctions to respective R_{target} values and thereby tune superconducting qubits in a qubit lattice on a quantum chip to respective target transition frequencies as specified by a frequency tuning plan. The tuning process of FIG. 11 is configured to utilize hybrid tuning calibration data to accurately determine and configured laser annealing operations and controlled-current tuning operations, to precisely control the tuning of junction resistance of Josephson junctions.

Referring to FIG. 11, a quantum chip is placed on the X-Y-Z stage 142 of the prober unit 140, and the control system 110 commences an automated hybrid tuning process (block 1100). The quantum chip comprises a plurality of superconducting qubits arranged in a given qubit lattice. The tuning process accesses a frequency tuning plan generated for the given qubit lattice, and hybrid tuning calibration data associated with the Josephson junctions of the superconducting qubits (block 1101). In some embodiments, the frequency tuning plan specifies respective R_{target} values for the Josephson junctions, as well as tuning calibration parameters for use in configuring the laser annealing settings and controlled tuning currents for tuning the Josephson junctions of the superconducting qubits.

In some embodiments, an initial phase of the hybrid tuning process involves performing a laser tuning process to tune the Josephson junctions towards their respective junction resistances, as specified in the initial frequency tuning plan (block 1102). An exemplary process for performing the laser tuning process will be discussed in further detail below in conjunction with FIG. 12.

At the completion of the laser tuning process, a determination is made as to whether all of the Josephson junctions have been tuned to their respective target resistance values within a specified threshold (block 1103). For example, in some embodiments, a given Josephson junction is deemed to be tuned to it target junction resistance R_{target} if the actual junction resistance is at the target junction resistance R_{target} or near the target junction resistance R_{target} within some specified threshold percentage of the target junction resistance R_{target}, i.e.,

$$\frac{\vert {R}_{target} - {R}_{current} \vert}{{R}_{target}} \leq x ( e . g . , x = 0.003 ( or 0.3 \% ) ) .$$

With each Josephson junction having a junction resistance which is at or near its target junction resistance R_{target}, it is assumed that each corresponding superconducting qubit has been tuned successfully and within a corresponding bound of precision to its respective target transition frequency.

If it is determined that each of the Josephson junctions have been tuned to their respective target resistance values within the specified threshold (affirmative determination in block 1103), the junction tuning process is deemed complete and the hybrid tuning process is ended (block 1104). In this instance, controlled-current tuning is not needed to further tune the junction resistance of the Josephson junctions. On the other hand, if it is determined that one or more of the Josephson junctions have not reached their respective target resistance values within the specified threshold as a result of the laser tuning (negative determination in block 1103), the hybrid tuning process can continue by performing a controlled-current tuning process to further tune such Josephson junctions to their target junction resistance. This situation arises, for example, when the target junction resistance of a given Josephson junction cannot be reached using laser tuning, e.g., the amount of resistance shift ΔR to reach the target junction resistance exceeds a maximum tuning range that is achievable using laser annealing.

Before proceeding with the controlled-current tuning process, a determination is made as to whether the existing frequency tuning plan is still viable to proceed with the controlled-current tuning of the laser annealed Josephson junctions which have not yet reached their respective target junction resistances (block 1105). For example, there can be instances where some of the remaining (laser annealed) Josephson junctions to be tuned cannot reach their target junction resistances using controlled-current tuning. Such determination can be made based on analyzing the hybrid tuning calibration data to determine whether or not the target junction resistance of a given laser annealed Josephson junction can be reached using controlled-current tuning. For example, there can be a situation where the remaining amount of resistance shift ΔR needed to reach the target junction resistance exceeds a maximum tuning range that is achievable using controlled-current tuning.

In this regard, if it is determined that the existing frequency tuning plan is still viable to proceed with the controlled-current tuning of the laser annealed Josephson junctions which have not yet reached their respective target junction resistances (affirmative determination in block 1105), the hybrid tuning process proceeds to perform a controlled-current tuning process to tune the remaining Josephson junctions to their respective target junction resistances (block 1106). In some embodiments, the controlled-current tuning process is performed using the same or similar process flow of FIG. 4, as discussed above, the details of which need not be repeated. In this instance, the hybrid calibration data is utilized to determine controlled tuning current parameters for generating and applying controlled tuning currents which are suitable to further tune the remaining (laser annealed) Josephson junctions to their respective target junction resistances.

On the other hand, if it is determined that the existing frequency tuning plan is not viable to proceed with the controlled-current tuning of the laser annealed Josephson junctions which have not yet reached their respective target junction resistances (negative determination in block 1105), the hybrid tuning process proceeds to generate a new or updated frequency tuning plan (block 1107) based on the existing state of the junction resistances of the Josephson junctions of the qubits within the give qubit lattice. In some embodiments, the new or updated frequency tuning plan is generated using a process which is the same or similar to the process discussed above in conjunction with FIG. 9, the details of which need not be repeated. The hybrid tuning process then proceeds to perform a controlled-current tuning process to tune the Josephson junctions to their respective target junction resistances, as needed, to meet the new or updated frequency tuning plan (block 1106).

FIG. 12 illustrates a flow diagram of a method of a laser tuning process which can be implemented in the hybrid tuning process of FIG. 11, according to according to an exemplary embodiment of the disclosure. In particular, FIG. 12 illustrates an exemplary laser tuning process in which the hybrid tuning calibration parameters can be used to calibrate the initial laser tuning operations (initial shots) that are performed on Josephson junctions to partially tune the Josephson junctions to respective target junction resistances by an amount that corresponds to an initial tuning resistance shift ΔRᵢₙᵢₜᵢₐₗ=F×ΔR_{target}, followed by an iterative adaptive tuning process to further laser tune the junction resistances of the Josephson junctions towards their respective target junction resistances. In some embodiments, an initial tuning factor of F≅50% is chosen to appreciably tune the Josephson junctions toward their target junction resistances R_{target}, while mitigating the risk of overshooting R_{target}.

As noted above, after placing the quantum chip on the X-Y-Z stage 142 of the prober unit 140, as an initial phase of the hybrid tuning process, a laser tuning process is commenced (block 1200). Again, the quantum chip comprises a plurality of superconducting qubits arranged in a given qubit lattice, and the hybrid tuning process utilizes the hybrid tuning calibration data to determine suitable laser power settings, anneal times, and (optionally) laser beam illumination patterns for configuring the laser tuning process to laser anneal the Josephson junctions of the superconducting qubits to thereby shift the initial junction resistances of the Josephson junctions toward their respective R_{target} values, as specified in the frequency tuning plan.

The laser tuning process begins by selecting an initial Josephson junction (or group of Josephson junctions) of an initial superconducting qubit or quantum device in the quantum chip, and moving to the selected Josephson junction (block 1201). In particular, the control system 110 moves the X-Y-Z stage 142 to place the initial Josephson junction into the FOV) of the microscope unit 130. The tuning process initiates control operations to cause the microscope unit and the probe unit to perform a focus and alignment process to ensure a proper focus to the focal plane and proper alignment of the target Josephson junction within the FOV of the microscope unit 130 for the purpose of performing an in-situ Josephson junction resistance measurement (block 1202). The focus ensures that the sample plane (e.g., the plane which contains the target Josephson junction) is at the focal plane (i.e., plane of focus) of the objective lens 137. The focus can be adjusted by adjusting the Z position of the X-Y-Z stage 142. The alignment to the Josephson junction can be performed using a machine learning pattern recognition process to align the Josephson junction (or group of Josephson junctions) to the center of the FOV.

Next, the laser tuning process proceeds to measure the junction resistance of the target Josephson junction (block 1203). In particular, the tuning process measures an initial junction resistance Rᵢₙᵢₜᵢₐₗ of the Josephson junction. In some embodiments, the electrical probes 141 are landed on the contact pads with a fixed displacement distance and overdrive to ensure proper contact (e.g., a stable, low resistance contact). In some embodiments, the electrical probes 141 are vertically moved downward to contact the tips of the electrical probes 141 to the contact pads on the quantum chip. In other embodiments, as noted above the positions of the electrical probes 141 remain fixed, and the Z position of the X-Y-Z stage 142 is moved upward so that the contact pads on the quantum chip are moved into contact with the tips of the electrical probes 141 (in which case a second focus and alignment step can be performed subsequent to the junction resistance measurement and prior to the initial laser annealing step as discussed below).

In some embodiments, an in-situ junction resistance measurement is performed using a 4-wire (Kelvin) probe resistance measurement operation, as discussed above in conjunction with FIG. 2A. For example, in some embodiment, a constant current is passed through the Josephson junction, and a resulting voltage across the Josephson junction is measured, wherein the resistance of the Josephson junction is determined based on the magnitude of the constant current and the measured voltage. In some or other embodiments, the resistance is determined by sourcing and applying a constant voltage across the Josephson junction, and the resulting current is measured, where the resistance of the Josephson junction or Josephson junction network is determined based on the magnitude of the constant voltage and the measured current. Moreover, in some embodiments, contact resistance and contact stability checks are initially performed, prior to performing the junction resistance measurement, to ensure that the contact resistance is below a given threshold, and to ensure that the contact between the electrical probe and the contact pads of the Josephson junction are stable and not intermittent.

Next, the laser tuning process initiates control operations to cause the microscope unit 130 and the prober unit 140 to perform a focus and alignment process to ensure a proper focus to the focal plane and proper alignment of the target Josephson junction within the FOV of the microscope unit 130 for the purpose of performing a laser anneal operation (block 1204). The laser tuning process proceeds to determine a target combination of laser power, anneal time, and laser beam illumination pattern to configure the initial laser anneal operation (initial shot) in a manner that is sufficient to achieve a partial tuning of the Josephson junction (block 1205). For example, the initial laser anneal operation (initial shot) is configured to shift the resistance of a Josephson junction to an initial target resistance R_{initial_target} by configuring the initial laser annealing parameters to achieve an initial tuning resistance shift ΔRᵢₙᵢₜᵢₐₗ=F×ΔR_{target}, where ΔRᵢₙᵢₜᵢₐₗ=R_{initial_target}−Rᵢₙᵢₜᵢₐₗ. In some embodiments, as noted above, the initial tuning factor F is selected to be F˜50% to appreciably tune the Josephson junction towards its target junction resistance R_{target}, while mitigating the risk of overshooting R_{target} on the initial laser annealing shot. Moreover, as noted above, the computed value of ΔRᵢₙᵢₜᵢₐₗ is utilized to determine a resistance shift percentage ΔR % which, in turn, can be used to determine a given combination of laser power, anneal time, and laser beam illumination pattern, to calibrate the initial laser tuning operation (initial shot) to achieve the initial tuning resistance shift ΔRᵢₙᵢₜᵢₐₗ (based on the measured initial junction resistance Rᵢₙᵢₜᵢₐₗ, and the computation

$$Δ R \% = \frac{Δ {R}_{initial}}{{R}_{initial}} \times 100 \% ) .$$

The tuning process performs the initial laser anneal operation (initial shot) on the given Josephson junction using the determined combination of laser power setting, anneal time, and laser beam illumination pattern, to achieve the desired amount of positive resistance shift to target, or negative resistance shift to target, for the initial shot (block 1206). Exemplary laser tuning operations using different laser beam illumination patterns will be discussed in further detail below in conjunction with FIGS. 13A and 13B. After completion of the initial laser anneal operation for the given Josephson junction, the laser tuning process determines whether there are any remaining Josephson junctions that need to be initially tuned to their respective initial tuning resistance shift ΔRᵢₙᵢₜᵢₐₗ using an initial laser anneal operation (block 1207). If there are one or more Josephson junctions that need to be to be tested (affirmative determination in block 1207), the laser tuning process selects a next Josephson junction of a next superconducting qubit to be tuned (return to block 1201) and repeats the laser tuning operations (e.g., blocks 1202, 1203, 1204, 1205, and 1206 are repeated).

On the other hand, if it is determined that there are no remaining Josephson junctions that need to be tuned to their respective initial tuning resistance shift ΔRᵢₙᵢₜᵢₐₗ using an initial laser anneal operation (negative determination in block 1207), the laser tuning process proceeds to tune each Josephson junction to its respective target junction resistance R_{target} using an adaptive laser tuning process (block 1208). At the completion of the adaptive laser tuning process, the hybrid tuning process will proceed to block 1103 (FIG. 11) to perform a controlled-current tuning process, if needed (block 1209), as discussed above.

In some embodiments, an adaptive tuning process (block 1208) comprises an iterative laser tuning process for tuning the junction resistances of the Josephson junctions by implementing an asymptotic tuning methodology in which Josephson junctions of, e.g., qubits on a given multi-qubit device are adaptively and progressively tuned in an incremental manner to progressively shift junction resistances towards respective target junction resistances of the Josephson junctions. In some embodiments, adaptive and progressive tuning of a given Josephson junction is implemented by adaptively determining the anneal time (tₛₕₒₜ) for a given tuning iteration at a given laser power level based on a function of (i) an amount of resistance shift remaining (ΔR_{remaining}) to reach the target junction resistance, and (ii) a total amount of anneal time spent for previous laser anneal iterations applied to the Josephson junction.

For example, an exemplary function for determining an anneal time (tₛₕₒₜ) for a given “shot” at a given laser power level is expressed as:

$${t}_{shot} ( {N}_{A} ) = \frac{Δ {R}_{target} - Δ R}{Δ {R}_{target}} \cdot {\sum }_{i = 1}^{{N}_{A} - 1} {t}_{shot} ( i ) for [ {N}_{A} > 1 ] ,$$

where N_{A} denotes an anneal number (or “shot” number), where, as noted above, ΔR_{target} denotes a difference between a target junction resistance (R_{target}) of a given Josephson junction and an initial measured resistance (denoted Rᵢₙᵢₜᵢₐₗ) of the given Josephson junction before the initial anneal operation (at N_{A}=0), and where ΔR denotes a difference between Rᵢₙᵢₜᵢₐₗ and a currently measured junction resistance (denoted R_{current}) of the given Josephson junction, which is measured in a given iteration before applying the next “shot” based on the computed anneal time tₛₕₒₜ for the given iteration. In other words, ΔR_{target}=R_{target}−Rᵢₙᵢₜᵢₐₗ, ΔR=R_{current}−Rᵢₙᵢₜᵢₐₗ, and ΔR_{remaining}=R_{target}−R_{current}. In the context of an adaptive laser tuning process, the parameter R_{current} denotes a current junction resistance that is measured at the beginning of each successive iteration of the adaptive tuning process, and the computation tₛₕₒₜ is performed for each successive iteration of the adaptive tuning process to determine a target anneal time for performing the laser anneal operation for given iteration. In some embodiments, the laser power level that is used in each iteration is the same laser power level that was initially selected to perform the initial laser annealing operation (blocks 1205 and 1206). In the exemplary function for computing tₛₕₒₜ, the ratio

$$\frac{Δ {R}_{target} - Δ R}{Δ {R}_{target}} = \frac{Δ {R}_{remaining}}{Δ {R}_{target}}$$

provides a weight factor that represents a percentage of the amount of a remaining amount of resistance shift needed to reach the target junction resistance R_{target} of the given Josephson junction based on the total resistance shift needed to reach the target junction resistance R_{target} starting from the initial measured junction resistance Rᵢₙᵢₜᵢₐₗ of the given Josephson junction. In addition, the summation

$${\sum }_{i = 1}^{{N}_{A} - 1} {t}_{shot} ( i )$$

provides weight factor based on the sum total time of all anneal times (total amount of all determined tₛₕₒₜ times) of all previous laser anneal “shots” applied to the given Josephson junction. It is to be noted that the exemplary function for tₛₕₒₜ provides a linear combination of weight factors based on a product of ΔR_{remaining} and the total historical anneal time. In other embodiments, a function for computing tₛₕₒₜ can be based on other parameters and/or based on a non-linear function of the parameters ΔR_{remaining} and the total historical anneal time and/or other parameters, depending on, e.g., the application and/or the tuning characteristics of the Josephson junction as determined based on the associated tuning calibration data obtained using the calibration techniques as discussed herein.

Based the exemplary parameters of the function tₛₕₒₜ, at a given iteration of the tuning process, if the measured junction resistance indicates that there is a relatively large amount of resistance shift still needed to reach the target junction resistance R_{target}, the determined anneal time, tₛₕₒₜ, will be weighted (by the ratio

$$\frac{Δ {R}_{remaining}}{Δ {R}_{target}} )$$

to be longer. On the other hand, if there is a relatively small amount of resistance shift needed to reach the target junction resistance R_{target}, the anneal time, tₛₕₒₜ, will be weighted (by the ratio

$$\frac{Δ {R}_{r emaining}}{Δ {R}_{target}} )$$

to be shorter. As another example, if the summation

$${\sum }_{i = 1}^{{N}_{A} - 1} {t}_{shot} ( i )$$

at a given iteration (e.g., at a given N_{A}) of the tuning process indicates a relatively large total amount of annealing has been performed on the given Josephson junction, this provides an indication that the given Josephson junction is tuning slowly, so that the next anneal time, tₛₕₒₜ, will be weighted (by the sum total anneal time) to be relatively long. On the other hand, if the summation

$${\sum }_{i = 1}^{{N}_{A} - 1} {t}_{shot} ( i )$$

at a given iteration of the tuning process indicates a relatively small total duration of annealing has been performed on the given Josephson junction, this provides an indication that the given Josephson junction is tuning relatively fast, so that the next anneal time, tₛₕₒₜ, will be weighted (by the sum total anneal time) to be relatively short.

FIGS. 13A and 13B schematically illustrate methods for laser annealing a quantum device using different laser beam illumination patterns, according to an exemplary embodiment of the disclosure. In particular, FIGS. 13A and 13B schematically illustrate respective methods 1300 and 1301 for laser annealing the Josephson junction of a superconducting qubit using differ laser spot patterns, which can be implemented to perform the laser anneal operation in block 1206, FIG. 12. FIG. 13A schematically illustrates an exemplary FOV 1310, the exemplary superconducting qubit 210 (discussed above in in junction with FIG. 2A), and quad-spot laser beam pattern 1320. In some embodiments, the FOV 1310 represents the area of the object that is imaged by the microscope unit 130 (FIG. 1), wherein the size of the FOV 1310 is generally determined by the magnification of the objective lens. In the exemplary architecture of the microscope unit 130, the FOV of the objective lens is applied to an image sensor (e.g., focal plane array) of the camera. Since the image sensor is rectangular in shape, the images captured by the laser microscope unit have a rectangular FOV, as shown in FIG. 13A, which does not capture the full circular FOV from the objective lens.

In FIG. 13A, as discussed above, the superconducting qubit 210 comprises a transmon qubit which comprises the first and second superconducting pads 211 and 212 (which comprise electrodes of a coplanar parallel-plate capacitor structure), with the Josephson junction 213 coupled to, and disposed between, the first and second superconducting pads 211 and 212. FIG. 13A schematically illustrates an exemplary method 1300 for laser annealing the Josephson junction 213 using a quad-spot laser beam pattern 1320. The quad-spot laser beam pattern 1320 comprises four (4) laser beam spots which correspond to, e.g., four laser beams that are generated by a diffractive optical element (a 2-by-2 diffractive beam splitter) and focused onto a surface (focal plane) of a quantum chip via the laser microscope unit. The quad-spot laser beam pattern 1320 is aligned to the Josephson junction 213 such that two laser spots 1321 are positioned on one side (e.g., above) of the Josephson junction 213, and two laser spots 1322 are positioned on an opposite side (e.g., below) the Josephson junction 213. The quad-spot laser beam pattern 1320 is configured to illuminate (and heat) regions of the upper surface of the quantum chip in proximity to the Josephson junction 213, but not directly illuminate the Josephson junction 213. The quad-spot laser beam pattern 1320 is configured to uniformly heat the region surrounding the Josephson junction 213, without directly illuminating the Josephson junction 213 with a laser beam spot.

Next, FIG. 13B schematically illustrates a method 1301 for laser annealing a quantum device using a dual-spot laser beam illumination pattern, according to another exemplary embodiment of the disclosure. It is to be noted that FIG. 13B is similar to FIG. 13A except that FIG. 13B schematically illustrates an exemplary dual-spot laser beam pattern 1330 which is aligned to the Josephson junction 213 such that a first laser beam spot 1331 is positioned on one side (e.g., above) of the Josephson junction 213, and a second laser beam spot 1332 is positioned on an opposite side (e.g., below) the Josephson junction 213. The dual-spot laser beam pattern 1330 is configured to illuminate (and heat) regions of the upper surface of the quantum chip in proximity to the Josephson junction 213, but not directly illuminate the Josephson junction 213.

While exemplary embodiments of the disclosure have been described in the context of tuning superconducting qubits having a single Josephson junction (e.g., fixed frequency transmon qubits), it is to be understood that the exemplary hybrid tuning techniques can be readily applied to tune Josephson junctions of other types of superconducting quantum devices which implement two or more Josephson junctions, or a group of Josephson junctions forming a Josephson-junction network. Such superconducting quantum device include, but are not limited to, SQUID-based devices, flux-tunable qubits, flux-tunable couplers to mediate interactions between qubits for entanglement gate operations, Josephson junction traveling-wave parametric circuits (such as Josephson traveling-wave parametric amplifier (JTWPA) circuits, and Josephson traveling-wave frequency converter (JTWFC) circuits), etc. As noted above, the microscope unit 130 is configured to generate a wide variety of laser beam illumination patterns and thermal profiles for laser tuning a single Josephson or a group of Josephson junctions having different numbers and geometric configurations of Josephson junctions.

For example, while FIGS. 13A and 13B illustrate an exemplary superconducting qubit 210 comprising a single Josephson junction 213 (fixed frequency qubit), the superconducting qubit 210 can be made to be a flux-tunable superconducting qubit by including an additional Josephson junction coupled in parallel with the Josephson junction 213, thereby forming a SQUID by connecting two Josephson junctions in parallel between the first and second superconducting pads 211 and 212 to form a superconducting loop through which a magnetic flux is threaded to tune the operating frequency of the flux-tunable superconducting qubit. In this instance, a multi-spot laser illumination pattern can be utilized to concurrently tune the two Josephson junctions of the SQUID.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1400 of FIG. 14 contains an example of an environment for the execution of at least some of the computer code (block 1426) comprising data processing and control algorithms for performing various operations and function as discussed herein such as imaging, pattern recognition, junction resistance measurements, tuning calibration operations, tuning calibration data analysis, junction resistance tuning operations, generating/updating frequency tuning plans, and other computer automated control and data processing operations as discussed herein for performing the exemplary methods shown or otherwise explained in conjunction with, e.g., FIGS. 2A-13B. In some embodiments, as noted above, FIG. 14 schematically illustrates an exemplary architecture of a computing environment for implementing the control system 110 (FIG. 1) or portions thereof, for tuning superconducting quantum devices, according to an exemplary embodiment of the disclosure. In addition to block 1426, computing environment 1400 includes, for example, computer 1401, wide area network (WAN) 1402, end user device (EUD) 1403, remote server 1404, public cloud 1405, and private cloud 1406. In this embodiment, computer 1401 includes processor set 1410 (including processing circuitry 1420 and cache 1421), communication fabric 1411, volatile memory 1412, persistent storage 1413 (including operating system 1422 and block 1426, as identified above), peripheral device set 1414 (including user interface (UI), device set 1423, storage 1424, and Internet of Things (IoT) sensor set 1425), and network module 1415. Remote server 1404 includes remote database 1430. Public cloud 1405 includes gateway 1440, cloud orchestration module 1441, host physical machine set 1442, virtual machine set 1443, and container set 1444.

Computer 1401 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1430. As is well understood in the art of computer technology, and depending upon the technology, performance of a computer-implemented method may be distributed among multiple computers and/or between multiple locations. On the other hand, in this presentation of computing environment 1400, detailed discussion is focused on a single computer, specifically computer 1401, to keep the presentation as simple as possible. Computer 1401 may be located in a cloud, even though it is not shown in a cloud in FIG. 14. On the other hand, computer 1401 is not required to be in a cloud except to any extent as may be affirmatively indicated.

Processor set 1410 includes one, or more, computer processors of any type now known or to be developed in the future. Processing circuitry 1420 may be distributed over multiple packages, for example, multiple, coordinated integrated circuit chips. Processing circuitry 1420 may implement multiple processor threads and/or multiple processor cores. Cache 1421 is memory that is located in the processor chip package(s) and is typically used for data or code that should be available for rapid access by the threads or cores running on processor set 1410. Cache memories are typically organized into multiple levels depending upon relative proximity to the processing circuitry. Alternatively, some, or all, of the cache for the processor set may be located “off chip.” In some computing environments, processor set 1410 may be designed for working with qubits and performing quantum computing.

Computer readable program instructions are typically loaded onto computer 1401 to cause a series of operational steps to be performed by processor set 1410 of computer 1401 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1421 and the other storage media discussed below. The program instructions, and associated data, are accessed by processor set 1410 to control and direct performance of the inventive methods. In computing environment 1400, at least some of the instructions for performing the inventive methods may be stored in block 1426 in persistent storage 1413.

Communication fabric 1411 comprises the signal conduction paths that allow the various components of computer 1401 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1412 is any type of volatile memory now known or to be developed in the future. Examples include dynamic type random access memory (RAM) or static type RAM. Typically, the volatile memory is characterized by random access, but this is not required unless affirmatively indicated. In computer 1401, the volatile memory 1412 is located in a single package and is internal to computer 1401, but, alternatively or additionally, the volatile memory may be distributed over multiple packages and/or located externally with respect to computer 1401.

Persistent storage 1413 is any form of non-volatile storage for computers that is now known or to be developed in the future. The non-volatility of this storage means that the stored data is maintained regardless of whether power is being supplied to computer 1401 and/or directly to persistent storage 1413. Persistent storage 1413 may be a read only memory (ROM), but typically at least a portion of the persistent storage allows writing of data, deletion of data and re-writing of data. Some familiar forms of persistent storage include magnetic disks and solid-state storage devices. Operating system 1422 may take several forms, such as various known proprietary operating systems or open source Portable Operating System Interface type operating systems that employ a kernel. The code included in block 1426 typically includes at least some of the computer code involved in performing the inventive methods.

Peripheral device set 1414 includes the set of peripheral devices of computer 1401. Data communication connections between the peripheral devices and the other components of computer 1401 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1423 may include components such as a display screen, speaker, microphone, wearable devices (such as goggles and smart watches), keyboard, mouse, printer, touchpad, game controllers, and haptic devices. Storage 1424 is external storage, such as an external hard drive, or insertable storage, such as an SD card. Storage 1424 may be persistent and/or volatile. In some embodiments, storage 1424 may take the form of a quantum computing storage device for storing data in the form of qubits. In embodiments where computer 1401 is required to have a large amount of storage (for example, where computer 1401 locally stores and manages a large database) then this storage may be provided by peripheral storage devices designed for storing very large amounts of data, such as a storage area network (SAN) that is shared by multiple, geographically distributed computers. IoT sensor set 1425 is made up of sensors that can be used in Internet of Things applications. For example, one sensor may be a thermometer and another sensor may be a motion detector.

Network module 1415 is the collection of computer software, hardware, and firmware that allows computer 1401 to communicate with other computers through WAN 1402. Network module 1415 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1415 are performed on the same physical hardware device. In other embodiments (for example, embodiments that utilize software-defined networking (SDN)), the control functions and the forwarding functions of network module 1415 are performed on physically separate devices, such that the control functions manage several different network hardware devices. Computer readable program instructions for performing the exemplary inventive methods can typically be downloaded to computer 1401 from an external computer or external storage device through a network adapter card or network interface included in network module 1415.

WAN 1402 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1403 is any computer system that is used and controlled by an end user (for example, a customer of an enterprise that operates computer 1401), and may take any of the forms discussed above in connection with computer 1401. EUD 1403 typically receives helpful and useful data from the operations of computer 1401. For example, in a hypothetical case where computer 1401 is designed to provide a recommendation to an end user, this recommendation would typically be communicated from network module 1415 of computer 1401 through WAN 1402 to EUD 1403. In this way, EUD 1403 can display, or otherwise present, the recommendation to an end user. In some embodiments, EUD 1403 may be a client device, such as thin client, heavy client, mainframe computer, desktop computer and so on.

Remote server 1404 is any computer system that serves at least some data and/or functionality to computer 1401. Remote server 1404 may be controlled and used by the same entity that operates computer 1401. Remote server 1404 represents the machine(s) that collect and store helpful and useful data for use by other computers, such as computer 1401. For example, in a hypothetical case where computer 1401 is designed and programmed to provide a recommendation based on historical data, then this historical data may be provided to computer 1401 from remote database 1430 of remote server 1404.

Public cloud 1405 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1405 is performed by the computer hardware and/or software of cloud orchestration module 1441. The computing resources provided by public cloud 1405 are typically implemented by virtual computing environments that run on various computers making up the computers of host physical machine set 1442, which is the universe of physical computers in and/or available to public cloud 1405. The virtual computing environments (VCEs) typically take the form of virtual machines from virtual machine set 1443 and/or containers from container set 1444. It is understood that these VCEs may be stored as images and may be transferred among and between the various physical machine hosts, either as images or after instantiation of the VCE. Cloud orchestration module 1441 manages the transfer and storage of images, deploys new instantiations of VCEs and manages active instantiations of VCE deployments. Gateway 1440 is the collection of computer software, hardware, and firmware that allows public cloud 1405 to communicate through WAN 1402.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1406 is similar to public cloud 1405, except that the computing resources are only available for use by a single enterprise. While private cloud 1406 is depicted as being in communication with WAN 1402, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1405 and private cloud 1406 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A method, comprising:
measuring a resistance of a superconducting tunnel junction device;
determining a difference between the measured resistance of the superconducting tunnel junction device and a target resistance for the superconducting tunnel junction device; and
performing a hybrid tuning process to shift a resistance of the superconducting tunnel junction device from the measured resistance to the target resistance, the hybrid tuning process comprising a laser tuning process and a controlled-current tuning process.

2. The method of claim 1, wherein performing the hybrid tuning process comprises:
performing the laser tuning process to shift the resistance of the superconducting tunnel junction device towards the target resistance; and
in response to determining that the target resistance cannot be reached using the laser tuning process, performing the controlled-current tuning process by applying a controlled tuning current to the superconducting tunnel junction device to shift the resistance of the superconducting tunnel junction device to the target resistance.

3. The method of claim 2, wherein performing the laser tuning process comprises:
utilizing tuning calibration data to determine a set of laser annealing parameters, based at least on the determined difference between the measured resistance of the superconducting tunnel junction device and the target resistance; and
utilizing the determined set of laser annealing parameters to configure the laser tuning process to laser anneal the superconducting tunnel junction device.

4. The method of claim 3, wherein the set of laser annealing parameters comprises at least a laser power setting and an anneal time, for a given laser beam illumination pattern.

5. The method of claim 2, wherein performing the controlled-current tuning process comprises:
utilizing tuning calibration data to determine a set of tuning current parameters, based at least on a remaining amount of resistance shift which is needed following the laser tuning process to reach the target resistance of the superconducting tunnel junction device; and
utilizing the determined set of tuning current parameters to configure the controlled-current tuning process to apply a controlled tuning current to the superconducting tunnel junction device.

6. The method of claim 5, wherein:
the controlled tuning current comprises a direct current (DC) current pulse; and
the set of tuning current parameters for the DC current pulse comprises at least one of pulse amplitude and pulse duration.

7. The method of claim 5, wherein:
the controlled tuning current comprises an alternating current (AC) current pulse; and
the set of tuning current parameters for the AC current pulse comprises at least one of peak amplitude, peak-to-peak amplitude, duration, frequency, pulse envelope shape, and DC offset.

8. A method, comprising:
performing a tuning process to tune a transition frequency of at least one superconducting quantum bit of a quantum bit array on a quantum chip, wherein performing the tuning process comprises:
measuring a resistance of a Josephson junction of the at least one superconducting quantum bit;
determining a difference between the measured resistance of the Josephson junction and a target resistance for the Josephson junction which corresponds to a target transition frequency of the at least one superconducting quantum bit as specified in a frequency tuning plan for the quantum bit array; and
performing a hybrid tuning process to shift a resistance of the Josephson junction of the at least one superconducting quantum bit from the measured resistance to the target resistance, the hybrid tuning process comprising a laser tuning process and a controlled-current tuning process.

9. The method of claim 8, wherein performing the hybrid tuning process comprises:
performing the laser tuning process to shift the resistance of the Josephson junction of the at least one superconducting quantum bit towards the target resistance of the Josephson junction; and
in response to determining that the target resistance of the Josephson junction cannot be reached using the laser tuning process, performing the controlled-current tuning process by applying a controlled tuning current to the Josephson junction of the at least one superconducting quantum bit to shift the resistance of the Josephson junction to the target resistance.

10. The method of claim 9, wherein performing the laser tuning process comprises:
utilizing tuning calibration data to determine a set of laser annealing parameters, based at least on the determined difference between the measured resistance of the Josephson junction and the target resistance of the Josephson junction; and
utilizing the determined set of laser annealing parameters to configure the laser tuning process to laser anneal the Josephson junction of the at least one superconducting quantum bit.

11. The method of claim 10, wherein the set of laser annealing parameters comprises at least a laser power setting and an anneal time, for a given laser beam illumination pattern.

12. The method of claim 9, wherein performing the controlled-current tuning process comprises:
utilizing tuning calibration data to determine a set of tuning current parameters, based at least on a remaining amount of resistance shift which is needed following the laser tuning process to reach the target resistance of the Josephson junction of the at least one superconducting quantum bit; and
utilizing the determined set of tuning current parameters to configure the controlled-current tuning process to apply a controlled tuning current to the Josephson junction of the at least one superconducting quantum bit.

13. The method of claim 12, wherein:
the controlled tuning current comprises a direct current (DC) current pulse; and
the set of tuning current parameters for the DC current pulse comprises at least one of pulse amplitude and pulse duration.

14. The method of claim 12, wherein:
the controlled tuning current comprises an alternating current (AC) current pulse; and
the set of tuning current parameters for the AC current pulse comprises at least one of peak amplitude, peak-to-peak amplitude, duration, frequency, pulse envelope shape, and DC offset.

15. A method, comprising:
measuring a resistance of a superconducting tunnel junction device;
utilizing tuning calibration data to determine a controlled tuning current to apply to the superconducting tunnel junction device to shift a resistance of the superconducting tunnel junction device from the measured resistance to a target resistance; and
applying the controlled tuning current to the superconducting tunnel junction device to shift the resistance of the superconducting tunnel junction device to the target resistance.

16. The method of claim 15, wherein applying the controlled tuning current comprises applying a direct current (DC) current pulse to the superconducting tunnel junction device, wherein the DC current pulse comprises a given pulse duration and pulse amplitude.

17. The method of claim 15, wherein applying the controlled tuning current comprises applying an alternating current (AC) current pulse to the superconducting tunnel junction device, wherein the AC current pulse comprises one or more of: one or more frequency components; a peak amplitude; a peak-to-peak amplitude; a duration; and a pulse envelope shape.

18. The method of claim 15, further comprising:
determining a difference between the measured resistance of the superconducting tunnel junction device and the target resistance of the superconducting tunnel junction device;
wherein the tuning calibration data is utilized to determine the controlled tuning current based at least in part on the determined difference between the measured resistance and the target resistance of the superconducting tunnel junction device.

19. A method, comprising:
performing hybrid tuning calibration operations on first Josephson junctions by (i) performing laser annealing operations to laser anneal the first Josephson junctions using different combinations of laser annealing parameters and (ii) applying controlled tuning currents with different combinations tuning current parameters, to the first Josephson junctions;
determining junction resistance shifts of the first Josephson junctions as a result of the laser annealing calibration operations and applying the controlled tuning currents to the first Josephson junctions; and
utilizing the determined junction resistance shifts of the first Josephson junctions to determine calibration data for configuring a hybrid tuning process, which comprises a laser tuning process and a controlled-current tuning process, for tuning second Josephson junctions that correspond to the first Josephson junctions.

20. The method of claim 19, wherein applying the controlled tuning currents with different combinations of tuning current parameters, to the first Josephson junctions comprises applying the controlled tuning currents to the first Josephson junctions subsequent to laser annealing the first Josephson junctions.

21. The method of claim 19, wherein:
the different combinations of laser annealing parameters comprises unique combinations of at least laser power settings and anneal times;
the different combinations of tuning current parameters each comprise at least one of tuning current parameters of direct current (DC) current pulses, and alternative current (AC) current pulses.

22. A system, comprising:
a laser annealing apparatus;
a prober apparatus; and
a control system operatively coupled to the laser annealing apparatus and the prober apparatus;
wherein the control system is configured to control the laser annealing apparatus and the prober apparatus to perform a tuning process to tune a transition frequency of at least one superconducting quantum bit of a quantum bit array on a quantum chip, wherein in performing the tuning process, wherein in performing the tuning process, the control system is configured to:
utilize the prober apparatus to measure a resistance of a Josephson junction of the at least one superconducting quantum bit;
determine a difference between the measured resistance of the Josephson junction and a target resistance for the Josephson junction which corresponds to a target transition frequency of the at least one superconducting quantum bit as specified in a frequency tuning plan for the quantum bit array; and
utilize the laser annealing apparatus and the prober apparatus to perform a hybrid tuning process to shift a resistance of the Josephson junction of the at least one superconducting quantum bit from the measured resistance to the target resistance, the hybrid tuning process comprising a laser tuning process and a controlled-current tuning process.

23. The system of claim 22, wherein in performing the hybrid tuning process, the control system is configured to:
utilize the laser annealing apparatus to perform the laser tuning process to shift the resistance of the Josephson junction of the at least one superconducting quantum bit towards the target resistance of the Josephson junction; and
in response to determining that the target resistance of the Josephson junction cannot be reached using the laser tuning process, utilize the prober apparatus to perform the controlled-current tuning process by applying a controlled tuning current to the Josephson junction of the at least one superconducting quantum bit to shift the resistance of the Josephson junction to the target resistance.

24. The system of claim 23, wherein:
in performing the laser tuning process, the control system is configured to:
utilize tuning calibration data to determine a set of laser annealing parameters, based at least on the determined difference between the measured resistance of the Josephson junction and the target resistance of the Josephson junction; and
utilize the determined set of laser annealing parameters to configure the laser tuning process to laser anneal the Josephson junction of the at least one superconducting quantum bit; and
in performing the controlled-current tuning process, the control system is configured to:
utilize the tuning calibration data to determine a set of tuning current parameters, based at least on a remaining amount of resistance shift which is needed following the laser tuning process to reach the target resistance of the Josephson junction of the at least one superconducting quantum bit; and
utilize the determined set of tuning current parameters to configure the controlled-current tuning process to apply a controlled tuning current to the Josephson junction of the at least one superconducting quantum bit.

25. The system of claim 24, wherein:
the set of laser annealing parameters comprises at least a laser power setting and an anneal time, for a given laser beam illumination pattern;
the controlled tuning current comprises at least one of a direct current (DC) current pulse and alternating current (AC) current pulse;
the set of tuning current parameters for the DC current pulse comprises at least one of pulse amplitude and pulse duration; and
the set of tuning current parameters for the AC current pulse comprises at least one of peak amplitude, peak-to-peak amplitude, duration, frequency, pulse envelope shape, and DC offset.
